(19) United States
(12) Patent Application Publication
(10) Pub. No.: US 2011/0232726 A1
(43) Pub. Date: Sep. 29, 2011

(54) BARRIER LAMINATE, METHOD OF MANUFACTURING THE LAMINATE, GAS BARRIER FILM AND DEVICE

(76) Inventor: Satoshi AIBA, Ashigarakami-gun (JP)

(21) Appl. No.: 13/071,217

(22) Filed: Mar. 24, 2011

(30) Foreign Application Priority Data
Mar. 25, 2010 (JP) 2010-069319

(51) Int. Cl. H01L 31/048; B32B 27/08; B32B 5/00; B05D 3/10; C08F 2/50

(52) U.S. Cl. 136/251; 428/447; 428/339; 427/379; 427/508

(57) ABSTRACT

A method of manufacturing an organic/inorganic laminate including forming a first organic layer by laminating and hardening a composition containing (A) a polymerizable acidic compound, oligomer or polymer, (B) a polymerizable compound, and (C) a silane coupling agent on a first inorganic layer, and forming a second organic layer by laminating and hardening a composition containing (D) a polymerizable compound and (E) a (meth)acrylate having an aromatic group on the first organic layer or on one or more organic layers disposed on the first organic layer.

### CROSS-REFERENCE TO RELATED APPLICATIONS

The present application claims the benefit of priority from Japanese Patent Application No. 2010-69319 filed on March 25, the contents of which are herein incorporated by reference in their entirety.

### BACKGROUND OF THE INVENTION

1. Field of the Invention

The present invention concerns a barrier laminate and a gas barrier film, as well as a device using them. Further, the invention relates to a method of manufacturing the barrier laminate.

2. Description of the Related Art

Various studies have been made so far for films having a barrier property. For example, JP-A 2000-123971 describes a barrier laminate in which a moisture proof thin laminate film as an inorganic layer comprising SiO₂, etc. is formed on a substrate, and two or more organic layers containing an organic layer having aromatic groups are formed thereover. It is generally known that a barrier performance tends to be improved when an organic layer having aromatic groups is disposed since the surface of the organic layer having the aromatic groups is planarized and each of the layers can be laminated uniformly. On the other hand, the organic layer of the patent document does not contain an acidic group for cleaving a silane coupling group, and adhesion between the inorganic layer and the organic layer has been insufficient.

However, the application use of the barrier laminate has been extended in recent years, and it has been demanded to increase the adhesion between each of the layers for improving the physical strength of the barrier laminate. Meanwhile, JP-A 2010-6063 discloses a gas barrier film having a high barrier property in which an organic layer formed by polymerizing a polymerizable compound having an ethylenic double bond, an aromatic group, and a group causing silane coupling reaction is disposed on a substrate and an inorganic layer is laminated to the surface thereof by vacuum sputtering, thereby improving adhesion between the organic layer and the inorganic layer by the silane coupling reaction. While the patent document describes that the organic layer may comprise plural layers it contains no investigation on a case of actually providing a plurality of organic layers. Further, it contains no investigation for the surface smoothness of the organic layer in which an organic layer formed by polymerizing a polymerizable compound having an ethylenic double bond, an aromatic group, and a group causing silane coupling reaction is provided in a case of laminating the organic layers on a previously laminated inorganic layer.

### SUMMARY OF THE INVENTION

Under the situations described above, the present inventors further attempted to manufacture a barrier laminate in which organic layers are disposed on an inorganic layer while intending to improve adhesion between each of the layers in the barrier laminate. However, it has been found that adhesion between the organic layer and the inorganic layer is not satisfactory in a structure of providing the organic layers over the inorganic layer in the method described in JP-A 2010-6063. In addition, it has also been found that when a polymerizable compound having a silane coupling agent on the side chain is used for the organic layer at the outermost layer, the surface smoothness of the organic layer tends to be worsened. Further, improvement for the adhesion was attempted also in JP-A No. 2009-220343 by using a silane coupling agent in an intermediate layer between inorganic layers. However, it has been found that although adhesion with the lower inorganic layer can be attained, adhesion with the upper inorganic layer is still unsatisfactory and the smoothness at the surface of the organic layer tends to be worsened and, accordingly, a further improvement is necessary.

The invention intends to solve the problems described above and provide a barrier laminate in which an organic layer is disposed over an inorganic layer, adhesion between the organic layer and the inorganic layer is satisfactory and the surface smoothness of the organic layer at the outermost layer is favorable, as well as a method of manufacturing such a barrier laminate.

As a result of an earnest study made by the present inventors in view of the subjects described above, it has been found that when an organic layer is formed on a first inorganic layer, an acidic compound has to be added to the organic layer for cleaving a silane coupling agent in order to improve the adhesion between both of them. However, it has been found that while the adhesion between the first inorganic layer and the organic layer is improved by the method, the surface smoothness of the organic layer is worsened since bonding also occurs between silane coupling agents having an aromatic group and a group causing silane coupling reaction in the organic layer. That is, it has been found that the subject described above cannot be solved by merely disposing the first inorganic film to the layer below the organic layer and taking place reaction by using a usual silane coupling agent with respect to the method described in JP-A 2010-6063.

Then, the present inventors have found that the adhesion between each of the layers can be improved and the surface of the organic layer at the outermost layer can be planarized in the barrier laminate by adopting, as organic layers, a first organic layer containing an acidic compound and a silane coupling agent and a second organic layer containing a specified polymerizable compound containing an aromatic group. Further, it has newly found that the bending resistance of the barrier laminate can also be improved when the adhesion is improved.

Specifically, it has been found that the subject described above can be overcome by the following means.

[1] A method of manufacturing an organic/inorganic laminate comprising forming a first organic layer by laminating and hardening a composition for a first organic layer containing (A) an acidic compound which is a polymerizable acidic compound, oligomer or polymer, (B) a polymerizable compound, and (C) a silane coupling agent on a first inorganic layer; and forming a second organic layer by laminating and hardening a composition for a second organic layer containing (D) a polymerizable compound and (E) a (meth) acrylate having an aromatic group on the first organic layer or on one or more organic layers disposed on the first organic layer.
[2] A method of manufacturing an organic/inorganic laminate comprising forming a first organic layer by laminating and hardening a composition for a first organic layer containing (A) an acidic compound which is a polymerizable acidic compound, oligomer or polymer, (B) a polymerizable compound, an (C) a silane coupling agent on a first inorganic layer; forming a second organic layer by laminating and hardening a composition for a second organic layer containing (D) a polymerizable compound and (E) a (meth) acrylate having an aromatic group on the first organic layer or on one or more organic layers disposed on the first organic layer; and forming a second inorganic layer on the second organic layer.
[3] A method of manufacturing an organic/inorganic laminate described in [1] or [2], wherein the composition for the second organic layer is laminated on the first organic layer.
[4] A method of manufacturing an organic/inorganic laminate described in any one of [1] to [3], wherein a polyfunctional (meth)acrylate is contained as at least one of (B) the polymerizable compound in the composition for the first organic layer, or (D) the polymerizable compound in the composition for the second organic layer.
[5] A method of manufacturing an organic/inorganic laminate described in any one of [1] to [4], wherein a polyfunctional aromatic ring (meth)acrylate is contained as (E) the (meth)acrylate having the aromatic group in the composition for the second organic layer.
[6] A method of manufacturing an organic/inorganic laminate described in any one of [1] to [4], wherein a (meth)acrylate having a bisphenol skeleton is contained as (E) the (meth)acrylate having the aromatic group in the composition for the second organic layer.
[7] A method of manufacturing an organic/inorganic laminate described in any one of [1] to [6], wherein the main ingredient contained in the composition for the first organic layer and the main ingredient contained in the composition for the second organic layer are the same.
[8] A method of manufacturing an organic/inorganic laminate described in any one of [1] to [7], wherein (A) the acidic compound, which is the polymerizable acidic compound, oligomer, or polymer is an acidic (meth)acrylate, oligomer, or polymer thereof.
[9] A method of manufacturing an organic/inorganic laminate described in any one of [1] to [7], wherein (A) the acidic compound which is the polymerizable acid compound, oligomer thereof, or polymer is a phosphoric acid acrylate oligomer or polymer.
[10] A method of manufacturing an organic/inorganic laminate described in any one of [1] to [9], wherein at least one of the first inorganic layer and the second inorganic layer is an inorganic layer containing one of silicon oxide, silicon nitride, silicon oxynitride, and silicon carbide.
[11] A method of manufacturing an organic/inorganic laminate described in any one of [1] to [9], wherein each of the first inorganic layer and the second inorganic layer is an inorganic layer containing one of silicon oxide, silicon nitride, silicon oxynitride, and silicon carbide.
[12] A method of manufacturing an organic/inorganic laminate described in any one of [1] to [11], wherein each of the composition for the first organic layer and the composition for the second organic layer contains a solvent.
[13] A method of manufacturing an organic/inorganic laminate described in any one of [1] to [12], wherein each of the composition for the first organic layer and the composition for the second organic layer contains a photopolymerization initiator.
[14] A method of manufacturing an organic/inorganic laminate described in any one of [1] to [13], wherein the composition for the second organic layer contains (F) a silane coupling agent.
[15] A method of manufacturing an organic/inorganic laminate described in [14], wherein a compound identical with (F) the silane coupling agent contained in the composition for the second organic layer is contained as (C) the silane coupling agent contained in the composition for the first organic layer.
[16] A method of manufacturing an organic/inorganic laminate described in [14] or [15], wherein (C) the silane coupling agent contained in the composition for the first organic layer and (F) the silane coupling agent contained in the composition for the second organic layer independently have a dimethoxymethylsilyl group or a trimethoxysilyl group respectively.
[17] An organic/inorganic laminate manufactured by the method of manufacturing the organic/inorganic laminate described in any one of [1] to [16].
[18] An organic/inorganic laminate in which a first inorganic layer, a first organic layer containing a polymer, and a second organic layer containing a polymer are laminated in this order (where one or more organic layers may be laminated between the first organic layer and the second organic layer), wherein acidic groups and siloxane bonds are contained in the first organic layer, an M-O—Si bond is formed between an atom M constituting the first inorganic layer and an Si atom constituting the first organic layer, aromatic ring structures and siloxane bonds are contained in the second organic layer, and the acid value of the first organic layer is greater than the acid value of the second organic layer.
[19] An organic/inorganic laminate in which a first inorganic layer, a first organic layer containing a polymer, and a second organic layer containing a polymer are laminated in this order (where one or more organic layers may be laminated between the first organic layer and the second organic layer) wherein acidic groups and siloxane bonds are contained in the first organic layer, an M-O—Si bond is formed between an atom M constituting the first inorganic layer and an Si atom constituting the first organic layer, aromatic ring structures and siloxane bonds are contained in the second organic layer, the acidic value of the first organic layer is greater than the acidic value of the second organic layer, and an M′-O—Si bond is formed between an atom M′ constituting the second inorganic layer and an Si atom constituting the second organic layer.
[20] An organic/inorganic laminate described in [18] or [19], wherein the first organic layer is adjacent with the second organic layer.
[21] An organic/inorganic laminate described in any one of [18] to [20], wherein at least one of the first organic layer and the second organic layer contains a poly(meth)acrylate.
[22] An organic/inorganic laminate described in any one of [18] to [21], wherein the second organic layer contains poly(meth)acrylate having an aromatic group.
[23] An organic/inorganic laminate described in any one of [18] to [22], wherein the second organic layer contains a (meth)acrylate having a poly-bisphenol skeleton.
[24] An organic/inorganic laminate described in any one of [18] to [23], wherein the first organic layer contains a poly(meth)acrylate having an acidic group.
[25] An organic/inorganic laminate described in [24], wherein the acidic group is a phosphoric acid group.
[26] An organic/inorganic laminate described in any one of [19] to [25], wherein at least one of the first inorganic layer and the second inorganic layer is an inorganic layer containing one of silicon oxide, silicon nitride, silicon oxynitride, and silicon carbide.
[27] An organic/inorganic laminate described in any one of [19] to [25], wherein each of the first inorganic layer and the second inorganic layer is an inorganic layer containing one of silicon oxide, silicon nitride, silicon oxynitride, and silicon carbide.
[28] An organic/inorganic laminate described in any one of [19] to [27], wherein an Si atom constituting the siloxane bond contained in the first organic layer is connected with at least one kind of organic groups, and an Si atom constituting the siloxane bond contained in the second organic layer is connected to the same kind of the organic group as that of the organic group.
[29] An organic/inorganic laminate described in any one of [18] to [28], wherein the total thickness of the organic layers contained between the first inorganic layer and the second inorganic layer is from 0.1 to 50 μm.
[30] An organic/inorganic laminate described in any one of [18] to [29], which is a barrier laminate.
[31] A gas barrier film in which the organic/inorganic laminate described in any one of [18] to [30] is formed on a base film.
[32] A device using the gas barrier film described in [31] as a substrate.
[33] A device sealed by using the organic/inorganic laminate described in any one of [18] to [30] or the gas barrier film described in [31].
[34] A device described in [32] or [33], wherein the device is a solar battery or an organic EL device.

The invention can provide a barrier laminate in which an organic layer is disposed on an inorganic layer, the organic layer and the inorganic layer have good adhesion and bending resistance, and the organic layer at the outermost layer has good surface smoothness, as well as a method of manufacturing the barrier laminate.

### BEST MODE FOR CARRYING OUT THE INVENTION

The present invention is to be described in details. “- - - to - - -” in the present specification expressing a range of numerical values means that numerical values described before and after “to” are included in the range as a lower limit value and an upper limit value. Further, the organic EL element means an organic electroluminescence device in the invention. In the specification, (meth)acrylate is used for both of the meanings of acrylate and methacrylate.

### [Manufacturing Method of Barrier Laminate]

A method of manufacturing a barrier laminate of the invention (hereinafter also referred to as manufacturing method of the invention) includes a step of forming a first organic layer of laminating and hardening a composition for a first organic layer containing (A) an acidic compound which is a polymerizable acidic compound, oligomer, or polymer, (B) a polymerizable compound, and (C) a silane coupling agent on a first inorganic layer and a step of forming a second organic layer of laminating and hardening a composition for a second organic layer containing (D) a polymerizable compound and (E) a (meth)acrylate having an aromatic group on the first organic layer or on one or more organic layers disposed on the first organic layer.

Further, the method of manufacturing the barrier laminate of the invention preferably includes a step of forming a second inorganic layer on the second organic layer. Since the barrier laminate obtained by the method of manufacturing the barrier laminate of the invention has an organic layer of smooth surface, the barrier property of the barrier laminate of the invention can be further improved easily by the step of forming the second inorganic layer.

### <Formation of First Inorganic Layer>

### (Formation Method of First Organic Layer)

In the manufacturing method of the invention, any method may be used for the formation of the first inorganic layer so long as an intended thin film can be formed. For example, the manufacturing method includes physical vapor deposition methods (PVD) such as vapor deposition, sputtering, ion plating method, etc., various chemical vapor deposition methods (CVD), and a liquid deposition method such as plating or sol-gel method. In the manufacturing method of the invention, a plasma deposition method is preferably used for the formation of the first inorganic layer and the plasma CVD method is used more preferably. The invention is extremely useful in that a barrier laminate having high barrier property can be obtained even in a case of depositing a film through a plasma process by using a metal oxide.

The inorganic layer is preferably deposited in a clean room. The degree of cleanliness is preferably, class 10,000 or less and, more preferably, class 1,000 or less.

### (Ingredient Used for the First Inorganic Layer)

The ingredients used in the formation of the first inorganic layer are not particularly limited excepting that they contain a metal atom M, and the metal atom M can form an M-O—Si bond with respect to the Si atom as a constituent of the first organic layer. For example, they include metal oxides, metal nitrides, metal carbides, metal oxynitrides, or metal oxycarbides. Oxides, nitrides, carbides, oxynitrides, oxycarbides, etc. containing one or more metals selected from Si, Al, In, Sn, Zn, Ti, Cu, Ce, or Ta can be used preferably. Among them, oxides, nitrides, oxynitrides, or carbides of metals selected from Si, Al, In, Sn, Zn, and Ti are preferred, metal oxides, nitrides, oxynitrides or carbides of Si or Al are more preferred. They include particularly preferably one of silicon oxides, silicon nitrides, silicon oxynitrides, and silicon carbides and, further preferably silicon nitrides. They may also contain other elements as subsidiary elements.

### <Formation of First Organic Layer>

The manufacturing method of the invention has a feature in laminating and hardening a composition for the first organic layer containing (A) an acidic compound which is a polymerizable acidic compound, oligomer, or polymer, (B) a polymerizable compound, and (C) a silane coupling agent on the first inorganic layer.

Each of the ingredients contained in the composition for the first organic layer and the method of forming the first organic layer are to be described.

### {Formation Method of First Organic Layer}

The formation method of the first organic layer is not particularly limited but the layer can be formed by a known coating method, for example, solution coating method or vacuum vapor deposition. In the case of using the solution coating, the layer can be coated, for example, by dip coating, air knife coating, curtain coating, roller coating, wire bar coating, gravure coating, slide coating, or extrusion coating using a hopper described the specification of U.S. Pat. No. 2,681,294. The vacuum deposition method is not limited particularly but deposition methods such as vapor deposition, plasma CVD, etc. are preferred. In the invention, a polymer may be solution-coated, or a hybrid coating method incorporating an inorganic material as disclosed in JP-A 2000-323273 and 2004-25732, may also be used.

In the invention, a composition containing a polymerizable compound is preferably hardened under radiation of light. The radiated light is usually LTV-light by a high pressure mercury lamp or a low pressure mercury lamp. The radiation energy is preferably 0.1 J/cm² or higher and, more preferably, 0.5 J/cm² or higher. In a case of using a (meth)acrylate type compound as the polymerizable compound, since it suffers from polymerization inhibition due to oxygen in air, it is preferred to lower oxygen concentration or oxygen partial pressure during polymerization. In a case of lowering the oxygen concentration during polymerization by a nitrogen substitution method, the oxygen concentration is preferably 2% or less and, more preferably, 0.5% or less. In a case of lowering the oxygen partial pressure during polymerization by a depressurization method, the entire pressure is preferably 1,000 Pa or less and, more preferably, 100 Pa or less. It is particularly preferred to perform UV polymerization by radiating an energy at 0.5 J/cm² or higher under a pressure reduction condition of 100 Pa or less.

((A) Acidic Compound which is Polymerizable Acidic Compound, Oligomer, or Polymer)

The composition for the first organic layer contains (A) an acidic compound which is a polymerizable acidic compound, oligomer, or polymer. By incorporation of the polymerizable acidic compound, adhesion between the layers in the obtained laminate can be improved.

In the present specification, (A) the polymerizable acidic compound is a monomer containing an acidic group, for example of carboxylic acid, sulfonic acid, phosphoric acid, and phosphonic acid. The polymerizable acidic compound used in the invention is preferably a monomer containing carboxylic acid, sulfonic acid, phosphoric acid, and phosphonic acid, more preferably, a monomer containing a carboxylic acid group or a phosphoric acid group and, particularly preferably, a monomer containing a phosphoric acid group.

Further, in the present specification, the oligomer or the polymer of the polymerizable acidic compound means a polycondensate obtained by polymerization of monomers having an acidic group, for example, of carboxylic acid, sulfonic acid, phosphoric acid, and phosphonic acid.

The acidic compound, oligomer, or polymer which is the polymerizable acidic compound is preferably an acidic (meth)acrylate, oligomer, or polymer thereof and, more preferably, phosphoric acid acrylate, or oligomer or polymer thereof.

The acidic group of the acidic compound which is a polymerizable acidic compound, oligomer, or polymer is preferably present at the terminal end of a molecule.

For the acidic compound which is the oligomer or polymer, the polymerization degree or the molecular weight is not particularly limited but the molecular weight is, preferably, 100 to 10,000, more preferably, 200 to 8,000 and, particularly preferably, 400 to 6,000.

Further, the polymerization degree of the acrylic compound which is the oligomer or polymer is preferably 2 to 100, more preferably, 5 to 80 and, particularly preferably, 10 to 50.

For the polymerizable acidic compound and the acidic compound which is the oligomer or polymer, the polymerizable acidic compound is preferred with a view point of improving the adhesion.

Specific examples of (A) the polymerizable acidic compound, oligomer, or polymer used preferably in the invention are shown below but the invention is not limited to them.

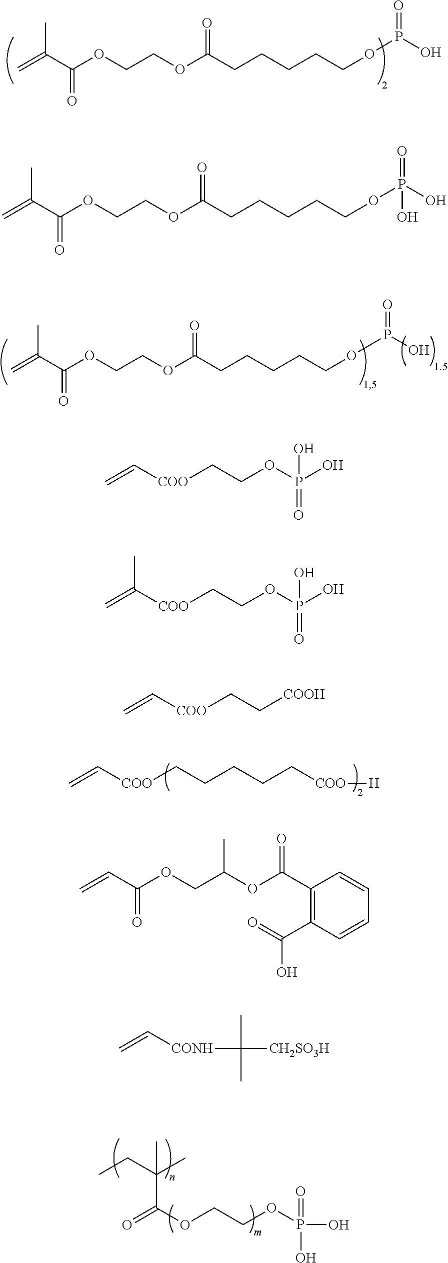

### ((B) Polymerizable Compound)

The composition for the first organic layer contains (B) the polymerizable compound.

The polymerizable compound is not particularly limited but known polymerizable compounds can be used.

In the manufacturing method of the invention, it is preferred to contain a polyfunctional (meth)acrylate as at least one of (B) the polymerizable compound in the composition for the first organic layer, or (D) the polymerizable compound in the composition for the second organic layer, with a view point of improving the bending resistance. Further, among the polyfunctional (meth)acrylates, bis- or higher functional acrylates are more preferred and tri- or higher functional acrylates are particularly preferred.

The polyfunctional monomer and other mother used as the polymerizable compound (B) are to be described below.

The polymerizable compound composition used in the invention preferably contains bifunctional (meth)acrylate. The barrier property and the surface smoothness of the organic layer are improved more by the incorporation of the bi-functional (meth)acrylate. Specifically, preferred examples include, for example, ethylene glycol di(meth)acrylate, propylene glycol di(meth)acrylate, butylene glycol di(meth)acrylate, neopentyl glycol di(meth)acrylate, and hexane diol di(meth)acrylate.

Specific examples of the bifunctional acrylate type compound are shown below but the invention is not limited to them.

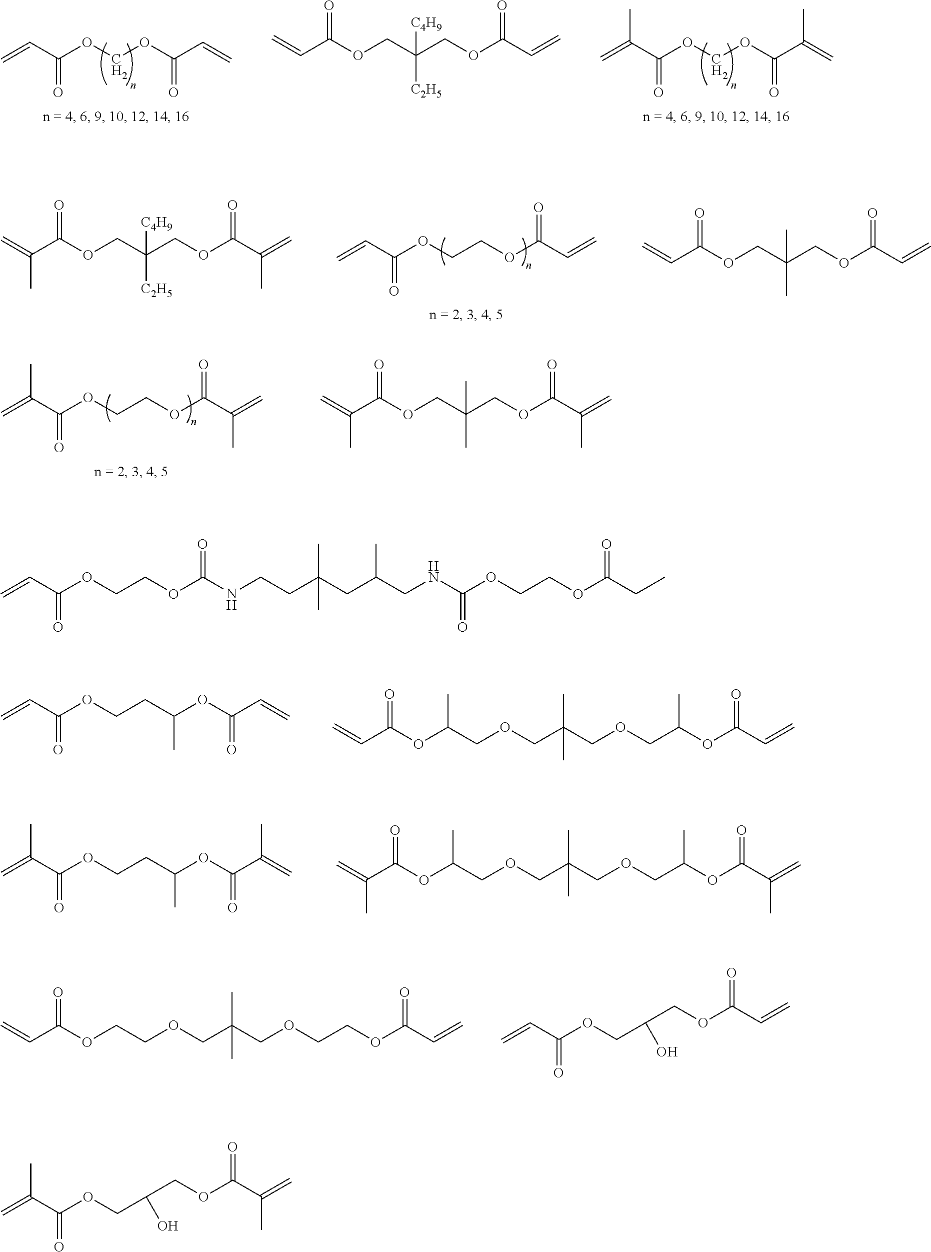

Further, while two or more types of bi-functional monomers may be incorporated, it is preferred that the bi-functional monomer is not contained in the composition for the first organic layer with a view point of improving the barrier property.

(B) the polymerizable composition contained in the first organic layer in the invention may include other monomer within a range not departing the gist of the invention. In the composition for the first organic layer, a tri-functional acrylate is preferably incorporated as (B) the polymerizable compound and, more preferably, only the tri-functional acrylate is incorporated, with a view point of improving the barrier property. In the followings, while specific examples of tri- or higher functional monomers are shown, the invention is not limited to them.

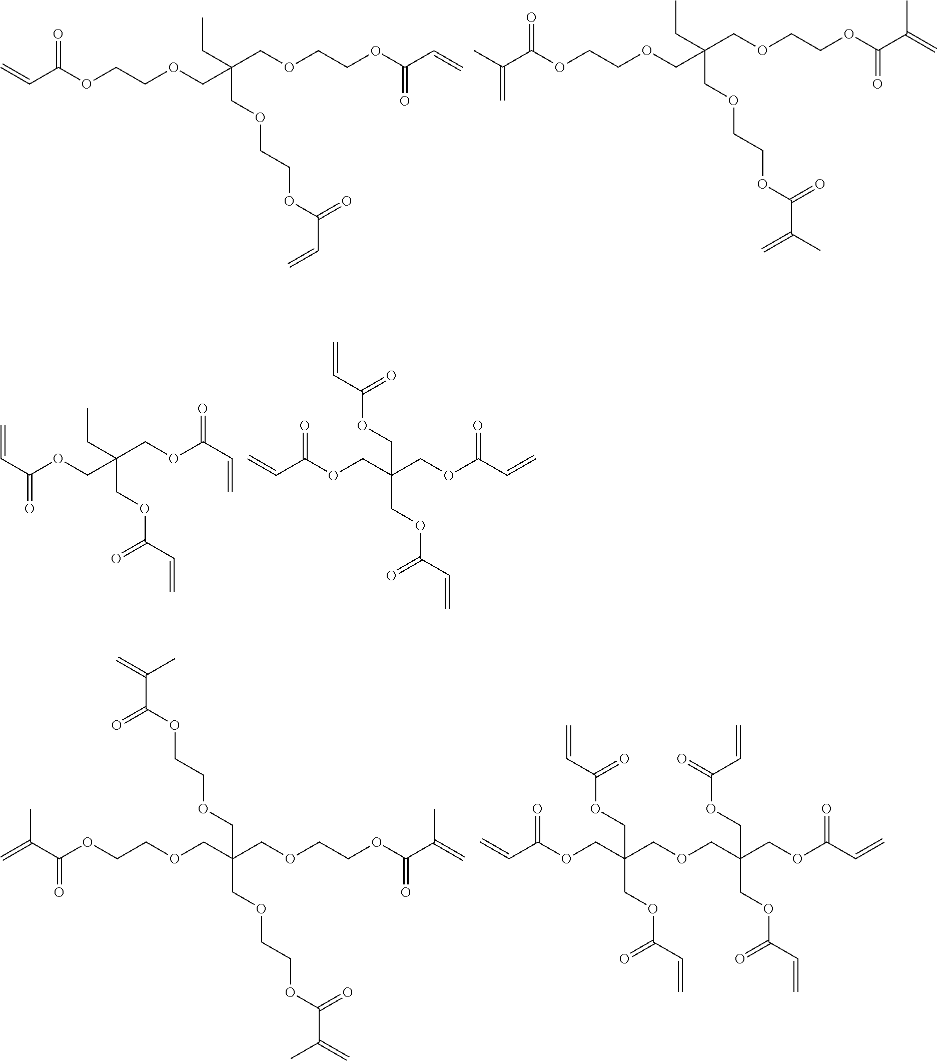

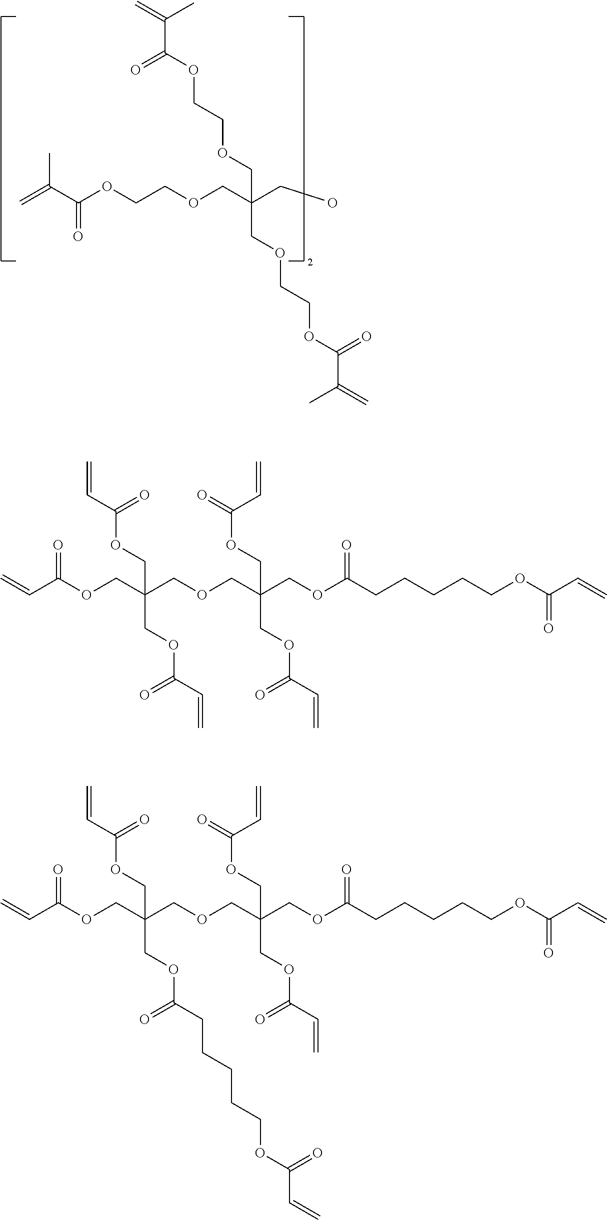

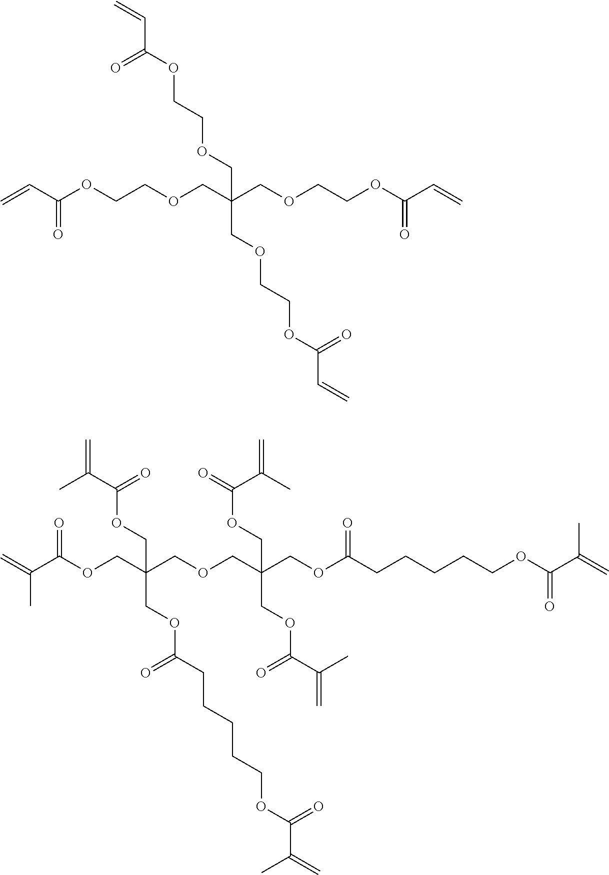

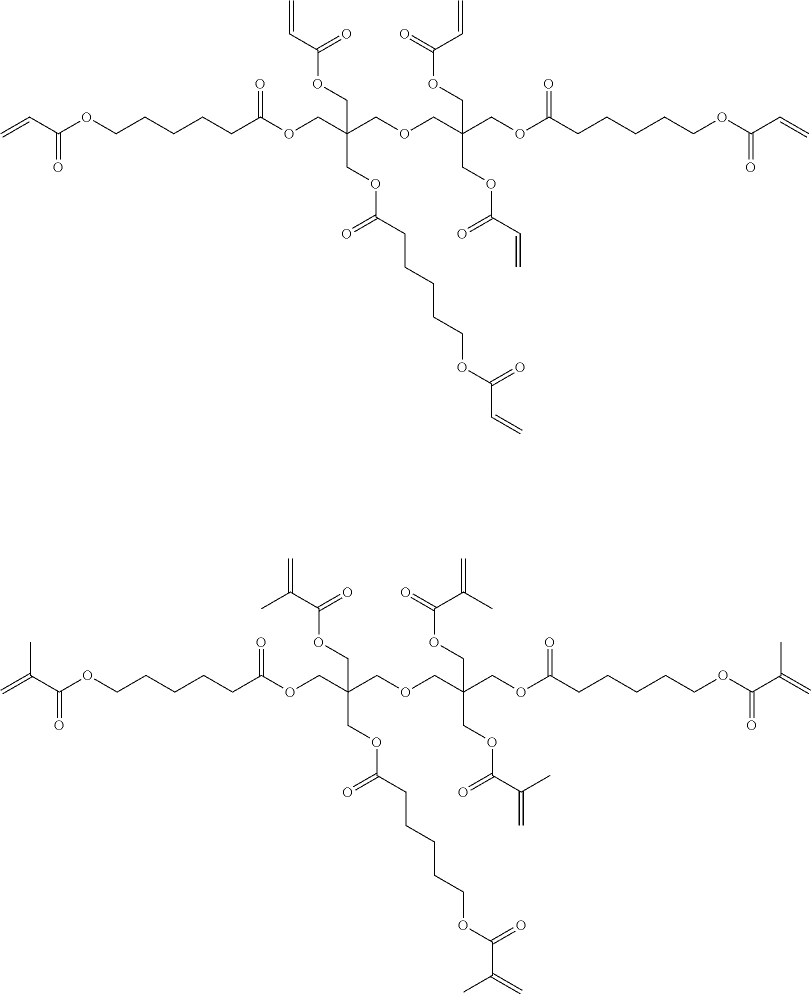

The composition for the first organic layer used in the invention may contain, within a range not departing the gist of the invention, monofunctional monomers and monomers other than (meth)acrylate (for example, styrene derivatives, maleic acid anhydride derivatives, epoxy compounds, and oxetane derivative), various kinds of polymers (for example, polyester, methacrylic acid-maleic acid copolymer, polystyrene, transparent fluororesin, polyimide, fluoropolyimide, polyamide, polyamidimide, polyetherimide, cellulose acylate, polyurethane, polyether ketone, polycarbonate, alicyclic polyolefin, polyarylate, polyether sulfone, polysulfone, fluorene ring-modified polycarbonate, alicyclic-modified polycarbonate, and fluorene ring-modified polyester).

On the other hand, it is preferred that the composition for the first organic layer does not contain (E) the (meth)acrylate having the aromatic group in the composition for the second organic layer to be described later.

Further, it is preferred that the composition for the first organic layer does not contains a trifunctional acrylate as (B) the polymerizable compound.

The ratio of the addition amount of (A) the acidic compound which is the polymerizable acidic compound, oligomer, or polymer thereof/(B) the polymerizable compound (mass ratio) in the composition for the first organic layer is, preferably, 1/2 to 1/200, more preferably, 1/5 to 1/100 and, particularly preferably, 1/10 to 1/40.

### ((C) Silane Coupling Agent)

The composition for the first organic layer contains (C) a silane coupling agent.

(C) the silane coupling agent is not particularly limited and known silane coupling agents can be used.

Among them, in the manufacturing method of the invention, (C) the silane coupling agent contained in the composition for the first organic layer preferably has a dimethoxymethylsilyl group or a trimethoxysilyl group. Further, among the silane coupling agents, the coupling agent preferably has a trimethoxysilyl group, with a view point of improving the adhesion.

It is preferred that (C) the silane coupling agent does not contain the aromatic group with a view point that the surface of the first organic layer can be planarized and the surface of a second organic layer to be described later can be planarized when the second organic layer is laminated and hardened.

(C) the silane coupling agent may or may not have a polymerizable group. In a case where it has the polymerizable group, it is preferably a (meth)acrylate group. Further, (C) the silane coupling group may be monofunctional or polyfunctional and it is preferably monofunctional.

Preferred examples of the silane coupling agent (C) contained in the composition for the first organic layer can include the following compounds but the invention is not limited to them.

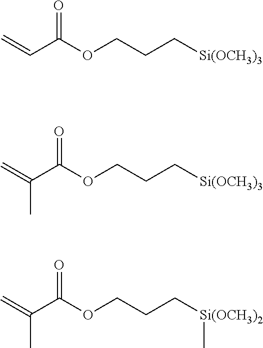

The ratio of the addition amount (mass ratio) of (A) the acidic compound which is the polymerizable acidic compound, oligomer, or polymer/(C) silane coupling agent in the composition for the first organic layer is, preferably, 1/1 to 1/50, more preferably, 1/2 to 1/20 and, particularly preferably, 1/3 to 1/10.

The ratio of the addition amount (mass ratio) of (C) the silane coupling agent/(B) the polymerizable compound in the composition for the first organic layer is, preferably, 1/1 to 1/50, more preferably, 1/2 to 1/20 and, particularly preferably, 1/3 to 1/10.

### (Polymerization Initiator)

The composition for the first organic layer in the invention may also contain a polymerization initiator and, among them, it is preferred to contain a photopolymerization initiator.

In a case where the photopolymerization initiator is used, the content thereof is, preferably, 0.1 mol % of more and, more preferably from 0.5 to 2 mol % based on the total amount of the polymerizing compounds contained in the first organic layer. With such a composition, polymerization reaction by way of an active ingredient forming reaction can be controlled properly. Examples of the photopolymerization initiator include Irgacure series (for example, Irgacure 651, Irgacure 754, and Irgacure 184, Irgacure 2959, Irgacure 907, Irgacure 369, Irgacure 379, Irgacure 819), Darocure series (for example, Darocure TPO, and Darocure 1173), and Quantacure PDO marketed from Ciba Speciality Chemicals Co., Ezacure series marketed from Lamberti Co. (for example, Ezacure TZM, Ezacure TZT, and Ezacure KTO46), etc., and oligomer type Ezacure KIP series marketed from Lamberti Co.

### (Solvent)

In the manufacturing method of the invention, the composition for the first organic layer preferably contains a solvent, and it is preferred to coat a composition containing the solvent.

The solvent usable in the invention includes, for example, alcoholic solvents, ketone type solvents, etheric solvents, THF, hydrocarbon solvents, and halogeno solvents. Among them, the alcoholic solvents and the ketone type solvents are preferred and 2-butanone is more preferred. The solvent used in the invention is not limited to them.

### <Formation of Second Organic Layer>

The manufacturing method of the invention includes a step of forming a second organic layer of laminating and hardening a composition for the second organic layer containing (D) the polymerizable compound and (E) the (meth)acrylate having an aromatic group on the first organic layer or on one or more organic layers disposed on the first organic layer.

### (Formation Method of Second Organic Layer)

The formation method of the second organic layer is not particularly defined and both of the lamination method and the hardening method of the composition for the second organic layer are identical with those of the preferred embodiment in the formation method of the first organic layer.

In the manufacturing method of the invention, it is preferred to laminate the composition for the second organic layer on the first organic layer with a view point of making the first organic layer and the second organic layer in adjacent with each other.

### ((D) Polymerizable Compound)

In the manufacturing method of the invention, the composition for the second organic layer contains (D) the polymerizable compound. Preferred examples of (D) the polymerizable compound are identical with the preferred examples of (B) the polymerizable compound used in the composition for the first organic layer.

In the manufacturing method of the invention, (D) the polymerizable compound in the composition for the second organic layer preferably contains a polyfunctional (meth)acrylate. Preferred examples of the polyfunctional (meth)acrylate used in (D) the polymerizable compound are identical with the preferred examples of the polyfunctional (meth)acrylate used preferably for (B) the polymerizable compound in the composition for the first organic layer.

In the manufacturing method of the invention, it is preferred that the main ingredient of the compound contained in the composition for the first organic layer and the main ingredient of the compound contained in the compound for the second organic layer are an identical compound. The main ingredient of the compound contained in the composition for the second organic layer is preferably (D) the polymerizable compound, and the main ingredient of the compound contained in the composition for the first organic layer is preferably (B) the polymerizable compound. That is, it is preferred that (B) the polymerizable compound contained in the composition for the first organic layer and (D) the polymerizable compound contained in the composition for the second organic layer are an identical compound with a view point of improving the adhesion between the organic layers.

Further, as described above, it is preferred that (D) the polymerizable compound as the main ingredient contained in the composition for the second organic layer is a trifunctional acrylate in the same manner as (B) the polymerizable compound as the main ingredient contained in the composition for the first organic layer.

### ((E) (Meth)Acrylate Having Aromatic Group)

In the manufacturing method of the invention, the composition for the second organic layer contains (E) the (meth)acrylate having the aromatic group. (E) the (meth)acrylate having the aromatic group used in the invention is not particularly limited and known (meth)acrylates having known aromatic group can be used.

The aromatic group of the (meth)acrylate having the aromatic group may be monovalent, bivalent, or higher valent and is preferably bivalent or trivalent and, more preferably, bivalent. That is, the (meth)acrylate having the aromatic group is, preferably, bivalent or trivalent (meth)acrylate and, more preferably, a bivalent (meth)acrylate.

The aromatic group of the (meth)acrylate having the aromatic group can include, for example, phenyl group, naphthyl group, bisphenol group, phenylene group, naphthylene group, bisphenol skeleton, fluorene skeleton, and cardo skeleton. Among them, the bisphenol skeleton, fluorine skeleton, and cargo skeleton are preferred, (meth)acrylate having the bisphenol skeleton is more preferred and, (meth)acrylate having the bisphenol A skeleton is particularly preferred.

While preferred examples of the (meth)acrylate having (E) the aromatic group can include the following compounds, the invention is not limited to them.

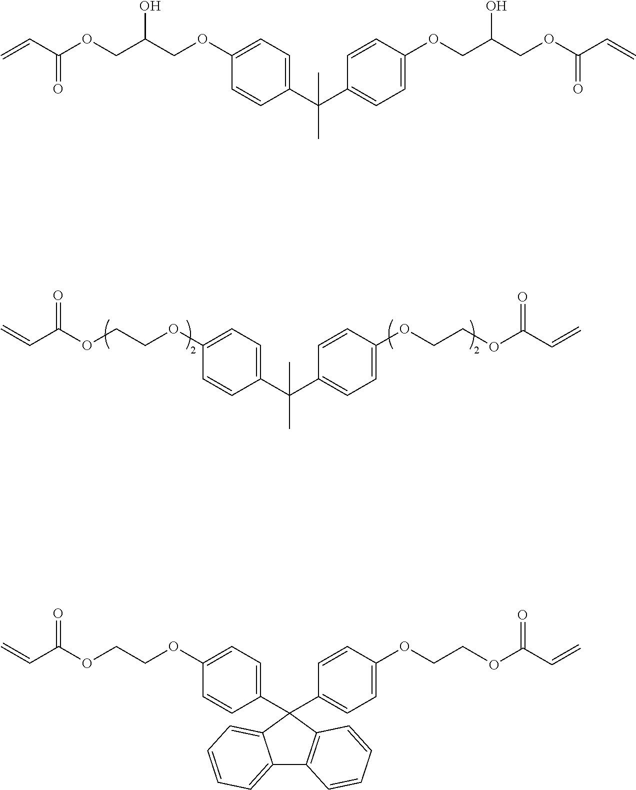

The ratio (mass ratio) of the addition amount of (D) polymerizable compound/(E) (meth)acrylate having the aromatic group in the composition for the second organic layer is preferably, 99/1 to 1/99, more preferably, 19/1 to 1/9 and, particularly preferably, 9/1 to 1/4.

### ((F) Silane Coupling Agent)

The composition for the second organic layer includes (F) silane coupling agents.

Among all, (F) the silane coupling agent contained in the composition for the second organic layer preferably has a dimethoxymethylsilyl group or a trimethoxysilyl group in the manufacturing method of the invention.

Preferred examples of (F) the silane coupling agent are identical with the preferred examples of (C) the silane coupling agent used in the composition for the first organic layer.

In the manufacturing method of the invention, it is preferred that compounds identical with (C) the silane coupling agent contained in the composition for the first organic layer is contained as (F) the silane coupling agent contained in the composition for the second organic layer with a view point of simplifying and stabilizing the manufacturing step.

In the composition for the second organic layer, the ratio (mass ratio) of the addition amount of (D) polymerizable compound/(F) silane coupling agent is, preferably, 1/1 to 1/50, more preferably, 1/2 to 1/20 and, particularly, preferably, 1/3 to 1/10.

On the other hand, it is preferred that the acidic compound which is the polymerizable acidic compound, oligomer, or polymer is not contained at all in the composition for the second organic layer with a view point of leaving the bonding site of (F) the silane coupling agent contained in the composition for the second organic layer without cleaving before the deposition of the second inorganic layer to be described later.

### (Photopolymerization Initiator)

In the manufacturing method of the invention, the composition for the second organic layer preferably contains a photopolymerization initiator, and preferred examples of the photopolymerization initiator are identical with the preferred examples of the photopolymerization initiator used in the composition for the first organic layer.

In the manufacturing method of the invention, both the composition for the first organic layer and the composition for the second organic layer preferably contain the photopolymerization initiator.

### (Solvent)

In the manufacturing method of the invention, the composition for the second organic layer preferably contains a solvent and preferred examples of the solvent are identical with the preferred examples of the solvent used in the composition for the first organic layer.

In the manufacturing method of the invention, both the composition for the first organic layer and the composition for the second organic layer preferably contain the solvent. When the solvent is contained, adhesion between the composition for the first organic layer and the composition for the second organic layer can be improved in a case of laminating the composition for the second organic layer on the first organic layer. Further, it is preferred that the solvent contained in the composition for the first organic layer and that in the composition for the second organic layer are an identical solvent with a view point of improving adhesion between the composition for the first organic layer and the composition for the second organic layer. By using the composition for each of the organic layers, a layer in which a boundary between the first organic layer and the second organic layer is not distinct and the composition changes continuously in the direction of the film thickness can be formed thereby improving the adhesion between the composition for the first organic layer and the composition for the second organic layer.

### <Formation of Other Organic Layers>

In the manufacturing method of the invention, other organic layer may also be formed.

The formation method of other organic layer is identical with the formation method for the first organic layer or the second organic layer.

Further, in a case of laminating the composition for the second organic layer on one or more of other organic layers disposed on the first organic layer, it is preferred that the composition for other organic layer further contains a solvent with a view point of improving the adhesion of the composition for the first organic layer, the composition for other organic layer, and the composition for the second organic layer.

### <Formation of Second Inorganic Layer>

In the manufacturing method of the invention, the manufacturing method for the second inorganic layer is not particularly limited but known methods can be adopted, and a method identical with the method described for the examples of the manufacturing method of the first inorganic layer can be used. Among them, the second inorganic layer is preferably manufactured by a plasma deposition method and, more preferably, by a plasma CVD method. The invention is extremely useful in that a barrier laminate having high barrier property can be obtained even in a case of deposition by a plasma process using a metal oxide as the material for the inorganic layer.

Further, the formation method of the second inorganic layer is not particularly limited and identical with the preferred embodiment of the formation method for the first inorganic layer. Further, the second inorganic layer preferably uses an ingredient containing a metal atom M′ which is identical with or different from that in the first inorganic layer and the atom M′ can form an M′-O—Si bond with relation to the Si atom constituting the second organic layer.

Further, in the barrier laminate of the invention, when it is not necessary to particularly improve the barrier property, ITO or aluminum may also be laminated as the second inorganic layer. Further, in this case, it is more preferred that the second organic layer does not contain the silane coupling agent.

### [Barrier Laminate]

The barrier laminate of the invention is an organic/inorganic laminate in which a first inorganic layer, a first organic layer containing a polymer, and a second organic layer containing a polymer are laminated in this order (where one or more organic layers may be laminated between the first organic layer and the second organic layer) and having a structure where acidic groups and siloxane bonds are contained in the first organic layer, an M-O—Si bond is formed between an atom M constituting the first inorganic layer and an Si atom constituting the first organic layer, aromatic ring structures and siloxane bonds are contained in the second organic layer, and an acid value of the first organic layer is greater than an acid value of the second organic layer.

According to the studies made by the present inventors, since the silane coupling agent contained in the first organic layer is cleaved by the acidic compound contained also in the first organic layer, adhesion between the first inorganic layer and the first organic layer can be improved. Further, since the aromatic ring structures are contained in the second organic layer, the surface smoothness of the second organic layer is high.

Further, the structure derived from the silane coupling agent may or may not be contained in the second organic layer. In a case where the structure derived from the silane coupling agent is contained, the structure derived from a compound different from the aromatic ring structure is preferred. Although it is not intended to be bound by any theory, when the silane coupling agent is a compound of a structure having a polymerizable group and an aromatic ring structure in one identical molecule, the group of the compound that causes silane coupling reaction is situated on the side chain in view of the aromatic ring structure. Accordingly, aromatic ring structures of the silane coupling agent of the structure having the polymerizable group and the aromatic ring structure in one identical molecule are less oriented toward the surface of the second organic layer since the groups causing silane coupling bonding are bonded to each other in the second organic layer or metal atom (M) in a second inorganic layer and the group causing the silane coupling bond are bonded in a case where the barrier laminate of the invention has the second inorganic layer to be described later. Accordingly, with a view point of improving the surface smoothness of the second organic layer, when the structure derived from the silane coupling agent is contained in the second organic layer, the structure is preferably such a structure derived from the compound different from the aromatic ring structure.

Further, in the barrier laminate of the invention, a second inorganic layer is preferably disposed on the second organic layer and, more preferably, an M′-O—Si bond is formed between an atom M′ constituting the second inorganic layer and an Si atom constituting the second organic layer.

The second organic layer may or may not contain the silane compound agent. When the silane coupling agent is contained, since the acid value of the second organic layer is smaller than the acid value of the first organic layer, silane coupling agents are less bonded to each other in the second organic layer. The adhesion between the second inorganic layer and the second organic layer can be improved. As a result, it is estimated that the barrier property and the adhesion are improved simultaneously.

The constitution for each of the layers of the barrier laminate of the invention is to be described specifically.

### (First Inorganic Layer)

The first inorganic layer is usually a thin film layer comprising a metal compound.

The barrier laminate of the invention has a feature that an M-O—Si bond is formed between an atom M constituting the first inorganic layer and an Si atom constituting the first organic layer. Due to the bonding, the barrier laminate of the invention has a high adhesion between the first inorganic layer and the first organic layer.

Ingredients contained in the first inorganic layer are not particularly limited so long as they satisfy the performance described above and, for example, are metal oxides, metal nitrides, metal carbides, metal oxynitrides, or metal oxycarbide. Oxides, nitrides, carbides, oxynitrides, and oxycarbides of metals selected from Si, Al, In, Sn, Zn, Ti, Cu, Ce, Ta, etc. can be used preferably. Among them, oxides, nitrides, oxynitrides, carbides, or the like of metals selected from Si, Al, In, Sn, Zn, and Ti are preferred. Particularly, oxides, nitrides, oxynitrides, carbides, etc. of metals of Si or Al are more preferred and it is preferred to that the first inorganic layer contains one of silicon oxides, silicon nitrides, silicon oxynitrides, and silicon carbides. They may also contain other elements as subsidiary ingredients.

Smoothness of the inorganic layer (formed) in the invention is preferably less than 1 nm and, more preferably, 0.3 nm or less in terms of an average roughness (Ra value) for 1 μm square.

The thickness of the inorganic layer is not particularly limited and it is usually within a range of 5 to 500 nm and, preferably, 10 to 200 nm. The inorganic layer may be a laminate structure comprising a plurality of sub-layers. In this case, each of the sub-layers may be of an identical or different composition. Further, as disclosed in the specification of US patent laid-open No. 2004-46497, the inorganic layer may be a layer in which the boundary with the first organic layer is not distinct and the composition changes continuously in the direction of the thickness.

### (First Organic Layer)

The first organic layer in the invention has a feature of containing a polymer and containing acidic groups and siloxane bonds, in which the acid value of the first organic layer is greater than the acid value of the second organic layer, and an M-O—Si bond is formed between an atom M constituting the first inorganic layer and an Si atom constituting the first organic layer. Since the barrier laminate of the invention has the M-O—Si bond as described above, it has a high adhesion and also has a preferred water vapor permeability.

The ingredients contained in the first organic layer include ingredients formed by polymerizing the composition for the first organic layer.

That is, the first organic layer preferably contains a poly(meth)acrylate and, more preferably, a poly(meth)acrylate having an acidic group. The acidic group is preferably a phosphoric acid group.

Further, in the barrier laminate of the invention, the acid value of the first organic layer is greater than the acidic value of the second organic layer.

Further, the barrier laminate of the invention preferably contains a poly(meth)acrylate in at least one of the first organic layer and the second organic layer.

Preferably, the first organic layer is smooth and has high film hardness. Smoothness of the organic layer is, preferably, less than 1 nm and, more preferably less than 0.5 nm in terms of an average roughness (Ra value) for 1 μm square. Degree of polymerization of the monomer is, preferably, 85% or more, more preferably, 88% or more, further preferably, 90% or more and, particularly preferably, 92% or more. The degree of polymerization referred to herein means the ratio of reacted polymerizable groups based on all of the polymerizing groups (acryloyl groups and methacryloyl groups) in the monomer mixture. The degree of polymerization can be quantitatively determined according to IR absorptiometry.

While the thickness of the first organic layer is not particularly limited, the uniformity of the thickness is less obtainable when the layer is excessively thin and, on the other hand, cracking may be generated by external force to lower the barrier property when it is excessively thick. Then, the thickness of the organic layer is, preferably, from 50 nm to 2000 nm and, more preferably, 200 nm to 1500 nm. As described above, the first organic layer is preferably smooth. It is required that obstacles such as particles and protrusions are not present on the surface of the organic layer.

The hardness of the first organic layer is preferably higher. It is known that, when the hardness of the organic layer is high, the inorganic layer can be formed smoothly and, as a result, the barrier performance of the gas barrier film is improved. The hardness of the organic layer can be expressed as microhardness based on a nanoindentation method. The microhardness of the organic layer is, preferably, 100 N/mm or more and, more preferably, 150 N/mm or more.

In the barrier laminate of the invention, the first organic layer is preferably in adjacent with the second organic layer with a view point of improving the adhesion between the first organic layer and the second organic layer, and improving the water vapor permeability.

In the barrier laminate of the invention, it is preferred that the Si atom constituting the siloxane bond contained in the first organic layer is connected with at least one of organic groups and that the Si atom constituting the siloxane bond contained in the second organic layer is bonded to an organic group of a type identical with that of the organic group. That is, (C) the silane coupling agent contained in the composition for the first organic layer and (F) the silane coupling agent which may be contained in the composition for the second organic layer are, preferably, an identical compound.

### (Second Organic Layer)

The second organic layer in the invention has a feature of containing a polymer and containing siloxane bonds, in which the acid value of the first organic layer is greater than the acid value of the second organic layer.

The ingredients contained in the second organic layer may include an ingredient formed by polymerization of the composition for the second organic layer.

The second organic layer may or may not contain the silane coupling agent and, preferably contains the coupling agent in a case of further laminating a second inorganic layer to be described later. In a case where the second organic layer contains the silane coupling agent, it is preferred that an atom M′ constituting the second inorganic layer forms an M′-O—Si bond relative to an Si atom constituting the second organic layer with a view point of improving the adhesion of the barrier laminate.

It is preferred for the barrier laminate of the invention that the acid value of the first organic layer is greater than the acid value of the second organic layer and the acid value of the second organic layer is zero since this can leave the bonding site of (F) the silane coupling agent contained in the composition for the second organic layer without cleaving when the second organic layer is formed, and (F) the silane coupling agent contained in the composition for the second organic layer can be cleaved in the second inorganic layer subsequent plasma deposition. Such a constitution can provide an M′-O—Si bond between the atom M′ constituting the second inorganic layer and the Si atom constituting the second organic layer to further improve the adhesion between the second organic layer and the second inorganic layer and further improve the water vapor permeability.

preferred ranges for the smoothness, the thickness, and the film hardness of the second organic layer are identical with the preferred ranges of the first organic layer. The second organic layer may be a layer in which the boundary with the first organic layer is not distinct and the composition changes continuously in the direction of the thickness. With such a constitution, the adhesion between the first organic layer and the second organic layer can be improved further.

In a case where the boundary with the first organic layer is not distinct, the acid value of the first organic layer is defined as a value measured at the boundary between the first organic layer and the first inorganic layer, and the acid value for the second organic layer is defined as a value measured at the surface opposite to the first organic layer. In a case where the barrier laminate of the invention has the second inorganic layer, the acid value of the second organic layer is defined as the value measured at the boundary between the second organic layer and the second inorganic layer.

### (Other Organic Layer)

In a case of laminating other organic layer in addition to the first organic layer and the second organic layer, it is preferably designed such that each of the organic layers is within the preferred ranges described above. Other organic layer includes an intermediate organic layer between the first organic layer and the second organic layer, and an intermediate organic layer on the side of a base film between the first inorganic layer and the base film to be described later. In the manufacturing method of the invention, it is preferred that the intermediate organic layer is not formed between the first organic layer and the second organic layer with a view point of improving the adhesion between the first organic layer and the second organic layer. On the other hand, in the manufacturing method of the invention, it is preferred to form an intermediate organic layer on the side of a base film between the first inorganic layer and the base film to be described later with a view point of improving the adhesion. As described above, the other organic group may be a layer in which the boundary with the inorganic layer is not distinct and the composition changes continuously in the direction of the film thickness as disclosed in the specification of US Patent Laid-Open No. 2004-46497.

In the barrier laminate of the invention, the total thickness of the organic layers contained between the first inorganic layer and the second inorganic layer is, preferably, 0.1 to 50 μm, more preferably, 0.2 to 10 μm and, particularly preferably, 0.4 to 5 μm. The total film thickness of the organic layers contained between the first inorganic layer and the second inorganic layer means a total thickness for the thickness of the first organic layer and the thickness of the second organic layer in a case where the intermediate organic layer is not disposed between the first organic layer and the second organic layer, and means the total thickness for the thickness of the first organic layer, the thickness for the second organic layer, and the thickness for the intermediate organic layer in a case where the intermediate organic layer is disposed between the first organic layer and the second organic layer.

### (Second Inorganic Layer)

The second inorganic layer is usually a thin film layer comprising a metal compound. While this is not an essential constitution for the barrier laminate of the invention, the second inorganic layer is preferably laminated on the second organic layer with a view point of improving the barrier property. It is preferred that an M′-O—Si bond is formed between the atom M′ constituting the second inorganic layer and the Si atom constituting the second organic layer.

A preferred range for the ingredients contained in the second inorganic layer is identical with the preferred range of the ingredients contained in the first inorganic layer.

Preferred ranges for the smoothness, the thickness, and the film hardness of the second inorganic layer are identical with the preferred ranges of the first organic layer. Further, the second inorganic layer may be a layer in which the boundary with the second organic layer is not distinct and the composition changes continuously in the direction of the thickness as disclosed in the specification of US Patent Laid-Open No. 2004-46497.

### (Lamination of Organic Layer and Inorganic Layer)

The organic layer and the inorganic layer can be laminated by depositing the organic layer and the inorganic layer repetitively in accordance with a desired layer constitution except for containing the barrier laminate laminated in the order of first inorganic layer/first organic layer/second organic layer.

For example, they can be laminated in the order of base film/intermediate organic layer on the side of the base film/first inorganic layer/first organic layer/second organic layer, laminated in the order of base film/intermediate organic layer on the side of the base film/first inorganic layer/first organic layer/second organic layer/second inorganic layer, laminated in the order of base film/first inorganic layer/first organic layer/second organic layer/second inorganic layer/organic layer, laminated in the order of base film/first inorganic layer/first organic layer/intermediate organic layer/second organic layer/second inorganic layer, or laminated in the order of base film//intermediate organic layer on the side of the base film/first inorganic layer/first organic layer/intermediate organic layer/second organic layer/second inorganic layer.

The number of layers constituting the barrier laminate is not particularly laminated and, typically, it is preferably 2 to 30 layers and, more preferably, 3 to 20 layers. Further, other constituent layers than the organic layer and the inorganic layer may also be contained.

Further, the barrier laminate of the invention may also contain a so-called gradient material layer in which an organic region and an inorganic region changes continuously in the direction of the thickness for the composition constituting the barrier laminate. Examples of the gradient material include materials described in the article by Kim, et al., in “Journal of Vacuum Science and Technology A vol. 23, p 971 to 977 (2005 American Vacuum Society)”, and a continuous layer in which a boundary is not present between the organic region and the inorganic region as disclosed in the specification of US Patent Laid-Open No. 2004-46497, etc.

### (Functional Layer)

The barrier laminate of the present invention may also have a functional layer on the barrier laminate or at any other position. The functional layer is described in details in JP-A 2006-289627, in column Nos. 0036 to 0038. Examples of other functional layers than described above include matting agent layer, protective layer, solvent resistance layer, antistatic layer, planarizing layer, adhesion improving layer, light shielding layer, antireflection layer, hard coat layer, stress relaxing layer, antifogging layer, antifouling layer, layer used for printing, highly adhesive layer, etc.

### (Use of Barrier Laminate)

Generally, the barrier laminate of the invention is formed on a support. By selecting the support, the barrier laminate may be used in various applications. The support includes a base film, as well as various devices, optical members, etc. Specifically, the barrier laminate of the present invention may be used as a barrier layer of a gas barrier film. Further, the barrier laminate and the gas barrier film of the invention may be used for sealing devices that require barrier property. The barrier laminate and the gas barrier film of the invention are also applicable to optical members. They are to be described in details.

### <Gas Barrier Film>

The gas barrier film of the invention has a feature that a barrier laminate of invention is formed on a base film. In the gas barrier film of the invention, the barrier laminate of the invention may be provided only one surface of the base film, or may be provided on both surfaces thereof. The barrier laminate of the invention may be laminated in the order of an inorganic layer and an organic layer from the side of the base film, or may be laminated in the order of the organic layer and the inorganic layer. The uppermost layer of the laminate of the invention may be an inorganic layer or an organic layer.

The gas barrier film of the invention is a film substrate having a barrier layer that functions to block oxygen, moisture, nitrogen oxide, sulfur oxide, ozone, etc. in atmospheric air.

The number of the layers that constitute the gas barrier film is not particularly limited. Typically, it is, preferably, from 2 to 30 layers and, more preferably, 3 to 20 layers.

The gas barrier film may have any other constituent ingredients (for example, functional layers such as highly adhesive layer) than the barrier laminate and the base film. The functional layer may be disposed on the barrier laminate, between the barrier laminate and the base film, or on the base film on the side not provided with the barrier laminate (back surface).

### (Plastic Film)

In the gas barrier film of the invention, a plastic film is used usually as the base film. The material and the thickness of the plastic film to be used are not particularly limited so long as the film can support the laminate such as an organic layer, an inorganic layer, etc. and any plastic film may be optionally selected depending on the purpose of use. Specifically, the plastic film includes thermoplastic resins such as polyester resin, methacryl resin, methacrylic acid-maleic acid copolymer, polystyrene resin, transparent fluororesin, polyimide, fluoropolyimide resin, polyamide resin, polyamidimide resin, polyetherimide resin, cellulose acylate resin, polyurethane resin, polyether ether ketone resin, polycarbonate resin, alicyclic polyolefin resin, polyarylate resin, polyether sulfone resin, polysulfone resin, cycloolefin copolymer, fluorene ring-modified polycarbonate resin, alicyclic-modified polycarbonate resin, fluorene ring-modified polyester resin, acryloyl compound, etc.

In case where the gas barrier film of the invention is used as a substrate for a device such as an organic EL device to be described later, the plastic film preferably comprises a material having a heat-resistance. Specifically, the plastic film preferably comprises a highly heat-resistant transparent material having a glass transition temperature (Tg) of 100° C. or higher and/or a linear thermal expansion coefficient of 40 ppm/° C. or less. The Tg and the linear expansion coefficient can be controlled by additives, etc. The thermoplastic resin of the type described above includes, for example, polyethylene naphthalate (PEN: 120° C.), polycarbonate (PC: 140° C.), alicyclic polyolefin (for example, Zeonoa 1600: 160° C., manufactured by Nippon Zeon Co.), polyarylate (PAr: 210° C.), polyethersulfone (PES: 220° C.), polysulfone (PSF: 190° C.), cycloolefin copolymer (COC: compound described in JP-A2001-150584: 162° C.), polyimide (for example, Neopulim: 260° C., manufactured by Mitsubishi Gas Chemical Co.), fluorene ring-modified polycarbonate (BCF-PC, compound described in JP-A 2000-227603: 225° C.), alicyclic-modified polycarbonate (IP-PC, compound described in JP-A 2000-227603: 205° C.), and acryloyl compound (compound described in JP-A 2002-80616: 300° C.) (temperature in parenthesis denotes Tg). When high transparency is required in particular, the alicyclic polyolefin is preferably preferred.

In a case of using the gas barrier film of the present invention as a device such as an organic EL device, the plastic film should be transparent. That is, plastic films having a light transmittance usually of 80% or more, preferably, 85% or more and, more preferably, 90% or more are used. The light transmittance can be calculated by a method described in JIS-K7105, namely, by measuring a total light transmittance and an amount of scattered light by using an integrating sphere type light transmittance analyzer and subtracting a diffusion transmittance from the total light transmittance.

Even in a case of using the gas barrier film of the invention for display use, the transparency is not always required when it is not disposed on the side of an observer. Accordingly, in such a case, an opaque material can also be used as the plastic film. Examples of the opaque materials include polyimides, polyacrylonitriles, known liquid crystal polymers, etc.

The thickness of the plastic film to be used for the gas barrier film of the invention is properly chosen depending on the use and not particularly limited and it is typically from 1 to 800 μm and, preferably, from 10 to 200 μm. Such plastic films may also have a functional layer such as a transparent conductive layer and a primer layer. The functional layer is described in details in JP-A 2006-289627 in columns Nos. 0036 to 0038. Examples of the functional layer other than those described above include matting agent layer, protective layer, solvent resistant layer, antistatic layer, smoothening layer, adhesion improving layer, light shielding layer, antireflection layer, hard coat layer, stress relaxing layer, antifogging layer, antifouling layer, layer used for printing, and highly adhesive layer.

### <Device>

The device of the invention has a feature of using the gas barrier film of the invention as a substrate, or using the gas barrier film of the invention for sealing the device.

The barrier laminate and the gas barrier film of the invention can be used favorably for devices whose performance is deteriorated by chemical ingredients in air (for example, oxygen, moisture, nitrogen oxide, sulfur oxide, ozone, etc.). Examples of the devices include electronic devices, for example, organic EL device, liquid-crystal display device, thin-film transistor, touch panel, electronic paper, and solar cell). They are used more preferably for organic EL devices.

The barrier laminate of the invention may be used also for sealing devices. That is, a device per se is used as a support and a barrier laminate of the invention is provided on the surface thereof. The device may be covered with a protective layer before providing the barrier laminate.

The gas barrier film of the invention may also be used as a substrate of a device or as a film for sealing by a solid sealing method. The solid sealing is a method of forming a protective layer on a device, then stacking an adhesive layer and a gas barrier film thereon, and hardening them. The adhesive is not particularly limited and includes, for example, a thermosetting epoxy resin, a photocurable acrylate resin, etc.

### (Organic EL Device)

The device of the invention using the gas barrier film of the invention may include an organic EL device.

Examples of the organic EL device are described in details in JP-A 2007-30387.

### (Liquid-Crystal Display Device)

A reflection-type liquid crystal display device has a constitution including a lower substrate, a reflection electrode, a lower alignment film, a liquid crystal layer, an upper alignment film, a transparent electrode, an upper substrate, a λ/4 plate, and a polarizing film formed in this order from the bottom. The gas barrier film of the invention may be used as the transparent electrode substrate and the upper substrate. In color display, a color filter layer is further provided preferably between the reflection electrode and the lower alignment film, or between the upper alignment film and the transparent electrode. A transmission type liquid crystal display device has a constitution including a backlight, a polarizer, a λ/4 plate, a lower transparent electrode, a lower alignment film, a liquid crystal layer, an upper alignment film, an upper transparent electrode, an upper substrate, a λ/4 plate, and a polarizing film formed in this order from the bottom. The substrate of the present invention may be used as the upper transparent electrode and the upper substrate. In color display, a color filter layer is further provided preferably between the lower transparent electrode and the lower alignment film, or between the upper alignment film and the transparent electrode. The type of the liquid crystal cell is not particularly limited and includes, preferably, TN (twisted nematic) type, STN (super-twisted nematic) type, HAN (hybrid aligned nematic) type, VA (vertically alignment) type, ECB (electrically controlled birefringence) type, OCB (optically compensatory bend) type, CPA (continuous pinwheel alignment) type, or IPS (in-plane switching) type.

The gas barrier film of the invention can used also in combination with a polarizer. In this case it is preferred that the gas barrier laminate of the gas barrier film is directed inside of a cell and disposed in the innermost side (adjacent to the device). In the structure, since the gas barrier film is disposed at the inner side of the cell relative to the polarizer, a retardation value of the gas barrier film is important. As a mode of using the gas barrier film in such an arrangement, a gas barrier film using a base film having a retardation value of 10 nm or less and a circular polarizer ((quarter-wave plate)+(half-wave plate)+(linear polarizer)) are preferably used in lamination, or a linear polarizer is used preferably in combination with a gas barrier film using a base film having a retardation value of from 100 nm to 180 nm, which can be used as a quarter-wave plate.

Examples of the base film having a retardation of 10 nm or less include cellulose triacetate (FUJITAC, manufactured by Fujifilm Corporation), polycarbonate (PURE-ACE, manufactured by Teijin Chemicals Ltd., ELMECH, manufactured by Kaneka Corporation), cycloolefin polymers CARTON, manufactured by JSR Corporation, ZEONOR, manufactured by Zeon Corporation), cycloolefin copolymers (APEL (pellet), manufactured by Mitsui Chemicals, Inc., TOPAS (pellet), manufactured by Polyplastics Co., Ltd.), polyarylates (U100 (pellet), manufactured by Unitika Ltd.), and transparent polyimides (NEOPULIM, manufactured by Mitsubishi Gas Chemical Company).

Films obtained by properly stretching the film described above thereby being adjusted to have a desired retardation value can be used as the quarter-wave plate.

### (Solar Cell)

The gas barrier film of the invention can be used also as a sealing film for a solar cell device. Preferably, the barrier film of the invention is used in sealing such that the adhesive layer is on the side near the solar cell device. The solar cell device for which the barrier film of the invention is used preferably is not specifically limited and includes, for example, single crystal silicon-based solar cell device, polycrystalline silicon-based solar cell device, amorphous silicon-based solar cell device of a single-junction or tandem-structure, III-V Group compound semiconductor solar cell device comprising gallium-arsenic (GaAs), indium-phosphorus (InP), etc., II-VI Group compound semiconductor solar cell device comprising cadmium-tellurium (CdTe), etc., Group compound semiconductor solar cell device comprising copper/indium/selenium (so-called CIS type), copper/indium/gallium/selenium (so-called CIGS type), copper/indium/gallium/selenium/sulfur (so-called CIGSS type), etc., dye-sensitized solar cell device, organic solar cell device, etc. Among all, in the invention, the solar cell device is preferably a Group compound semiconductor solar cell device comprising copper/indium/selenium (so-called CIS type), copper/indium/gallium/selenium (so-called CIGS type), copper/indium/gallium/selenium/sulfur (so-called CIGSS type), etc.

### (Electronic Paper)

The gas barrier film of the invention can also be used as electronic paper. The electronic paper is a reflection type electronic display that can attain high fineness and high contrast ratio.

The electronic paper has a display medium and a TFT for driving the display medium on a substrate. For the display medium, any known display medium can be used. While any of display media of electrophoretic type, electronic particulate flying type, charged toner type, electrochromic type, etc. may be used preferably, the electrophoretic type display medium is more preferred and, among all, a display medium of micro encapsulated electrophoretic type is particularly preferred. The electrophoretic type display medium is a display medium containing a plurality of capsules, and each of the capsules contains at least one particle movable in a suspended fluid. At least one particle referred to herein is preferably an electrophoretic particle or a rotational ball. Further, the electrophoretic type display medium has a first surface and a second surface opposed to the first surface, and displays images for observation by way of one of the first and the second surfaces.

Further the TFT disposed over the substrate at least has a gate electrode, a gate insulating film, an active layer, a source electrode, and a drain electrode and, further, has an electrically connecting resistance layer at least between the active layer and the source electrode or between the active layer and the drain electrode. Electronic paper causes light and shade by the application of voltage.

In a case of manufacturing an electronic display of highly fine color display at high fineness, a TFT is preferably formed on a color filter for ensuring the alignment accuracy. However, even when a necessary driving current is intended to obtain by a usual TFT of low current efficiency, since there is a limit on the down sizing, the area of the TFT occupying in a pixel is increased as the fineness of the display medium becomes higher. When the area of the TFT occupying in the pixel increases, the aperture ratio is decreased to lower the contrast ratio. Therefore, even when a transparent amorphous IGZO type TFT is used, the light transmittance does not reach 100% and the contrast is lowered inevitably. Then, the area of the TFT occupying the pixel can be decreased to increase the aperture ratio and the contrast ratio by using a TFT as described, for example, in JP-A 2009-21554. Further, when the TFT of this type is formed directly on a color filter, higher fineness can also be attained.

### (Others)

Other applications of the invention include, for example, a thin-film transistor described in JP-T 10-512104 and touch panels described in JP-A 5-127822, 2002-48913, etc.

### <Optical Member>

Examples of the optical member using the gas barrier film of the invention include a circular polarizer, etc.

### (Circular Polarizer)

A circular polarizer can be manufactured by using a gas barrier film of the invention as a substrate and laminating a λ/4 plate and a polarizer thereover. In this case, they are laminated such that the slow axis of the λ/4 plate and the absorption axis of the polarizer define an angle of 45°. A polarizer stretched in the direction of 45° relative to the machine direction (MD) is used preferably and those, for example, described in JP-A 2002-865554 are used favorably.

### EXAMPLES

The present invention will be further specifically explained with reference to the following examples of the present invention. The materials, amounts, ratios, types and procedures of treatments and so forth shown in the following examples can be suitably changed unless such changes depart from the gist of the present invention. Accordingly, the scope of the present invention should not be construed as limited to the following specific examples.

### 1. Formation of Gas Barrier Film

As a base film, a polyethylene naphthalate film (PEN film, commercial name: TEONEX Q 65FA, manufactured by Teijin Dupont Co.) was cut into 20 cm square, and a barrier layer was formed on the side of the highly adhesive surface by the following procedures and evaluated.

### (1-0) Formation of Intermediate Organic Layer (Y-6) on the Side of Base Film

A polymerizable composition comprising 18.6 g of a composition for an intermediate organic layer Y-6 on the side of a base film, 1.4 g of an UV-ray polymerization initiator (ESACURE KT046, manufactured by Lamberti Co.), and 180 g of 2-butanone was coated to a liquid thickness of 5 μm on the base film and hardened under radiation of UV-light of a high pressure mercury lamp in a chamber conditioned to an oxygen concentration of 0.1% by a nitrogen substitution method (accumulated radiation dose: about 1 J/cm²), to form an intermediate organic layer having a thickness of 600 nm±50 nm on the side of the base film.

The composition for the intermediate organic layer Y-6 on the side of the base film contains 14.9 g of a polymerizable compound TMPAT and 3.7 g of a silane coupling agent SC-1 of the following structures.

### (1-1) Formation of First Inorganic Layer (X)

A silicon nitride layer as a first inorganic layer was adjusted to a thickness of 40 nm and formed on an intermediate organic layer on the side of the base film by using a CCP (Capacitively Coupled Plasma type)-CVD apparatus. As starting material gases, a silane gas (flow rate: 160 sccm), an ammonia gas (flow rate: 370 sccm), a hydrogen gas (flow rate: 590 sccm), and a nitrogen gas (flow rate: 240 sccm) were used. Further, the inorganic layer was deposited under a film deposition pressure of 40 Pa, by using a high frequency power source at a frequency of 13.56 MHz, and a plasma excitation power of 2.5 kW.

### (1-2) Formation of First Organic Layer

A composition for the first organic layer comprising a polymerizable composition (18.6 g) having compositions shown in the following Table 1, 1.4 g of a UV-polymerization initiator (ESACURE KT046, manufactured by Lamberti Co.), and 180 g of 2-butanone was coated at a (film) thickness of 5 μm on the first inorganic layer by using a wire bar and radiated with UV-light of a high pressure mercury lamp (accumulated radiation dose: about 1 J/cm²) in a chamber conditioned to an oxygen concentration of 0.1% by a nitrogen substitution method to harden the first organic layer and form the first organic layer having a thickness of 600 nm±50 nm.

In Comparative Examples 6 and 7, the first organic layer (organic layer containing an acidic compound which is a polymerizable acid compound, oligomer, or polymer) was not formed.

### (1-3) Formation of Intermediate Organic Layers (Y-1 to Y-5)

In Examples 11 to 15, intermediate organic layers were formed in the same manner as the first organic layer except for using polymerizable compounds having compositions shown in the following Table 3.

### (1-4) Formation of Second Organic Layer

Second organic layers were formed on the first organic layer in Examples 1 to 10, 16, and 17 and Comparative Examples 1 and 2, on the intermediate organic layer in Examples 11 to 15, and on the first inorganic layer in Comparative Examples 6 and 7, respectively, in the same manner as the first organic layer except for using polymerizable compounds having compositions shown in the following Table 2 and thickness of 400 nm±50 nm.

The second organic layer was not formed in Comparative Examples 3 to 5.

### (1-5) Formation of Second Inorganic Layer (X)

A silicon nitride film which is a second inorganic layer (X) was formed by using a CCP (Capacitively Coupled Plasma system)-CVD apparatus. The silicon nitride layer was formed at a thickness adjusted to 40 nm on the second organic layer in Examples 1 to 16 and Comparative Examples 1, 2, 6, 7 and on the first organic layer in Comparative Examples 3 to 5.

The following Tables 1 to 3 show the type and the mixing ratio of the polymerizable compounds used for the first organic layer, the second organic layer, and the organic layer in the examples.

TABLE 1

| | |
|---|---|
| Composition | |
| for first | Polymerizable compound/silane coupling |
| organic layer | agent/acidic compound (weight ratio) |

| | | |
|---|---|---|
| UL-1 | TMPAT/SC-1/PA | (14.1/3.5/1.0) |
| UL-2 | TMPAT/SC-1/CA-1 | (14.1/3.5/1.0) |
| UL-3 | TMPAT/SC-1/CA-2 | (14.1/3.5/1.0) |
| UL-4 | TMPAT/SC-2/PA | (14.1/3.5/1.0) |
| UL-5 | TMPAT/SC-3/PA | (14.1/3.5/1.0) |
| UL-6 | TMPAT/SC-1/PP | (14.1/3.5/1.0) |
| UL-7 | BEPGA/SC-1/PA | (14.1/3.5/1.0) |
| UL-8 | PETA/SC-1/PA | (14.1/3.5/1.0) |
| UL-9 | TMPAT/SC-1/PS | (14.1/4.0/0.5) |
| UL-11 | TMPAT/SC-1/Phosphoric acid | (14.1/3.5/1.0) |
| | (0.1% aqueous solution) | |
| UL-12 | TMPAT/SC-1/Hydrochloric acid | (14.1/3.5/1.0) |
| | (0.1% aqueous solution) | |

In Table 1, phosphoric acid and hydrochloric acid are acidic compounds which are neither polymerizable compound, oligomer, or polymer.

TABLE 2

| | |
|---|---|
| Composition | |
| for second | Polymerizable compound/silane coupling |
| organic layer | agent (weight ratio) |

| | | |
|---|---|---|
| TL-1 | TMPAT/BFA-1 | (14.9/3.7) |
| TL-2 | TMPAT/BFA-2 | (14.9/3.7) |
| TL-3 | TMPAT/FA | (14.9/3.7) |
| TL-4 | BEPGA/BFA-1 | (14.9/3.7) |
| TL-5 | PETA/BFA-1 | (14.9/3.7) |
| TL-6 | TMPAT/BFA-1/SC-1 | (14.1/3.5/1.0) |

TABLE 3

| | |
|---|---|
| Composition for | |
| intermediate | |
| organic layer | Polymerizable compound (weight ratio) |

| | | |
|---|---|---|
| Y-1 | TMPAT | (18.6) |
| Y-2 | BEPGA | (18.6) |
| Y-3 | PETA | (18.6) |
| Y-4 | TMPAT/BEPGA | (9.3/9.3) |
| Y-5 | TMPAT/PETA | (9.3/9.3) |
| Y-6 | TMPAT/BFA-1 | (14.9/3.7) |

### ((Meth)Acrylate Having Aromatic Group)

Structures of (meth)acrylates having aromatic groups are shown below.

BFA-1: NK OLIGO EA-1020, manufactured by Shin Nakamura Chemical Industry Co.

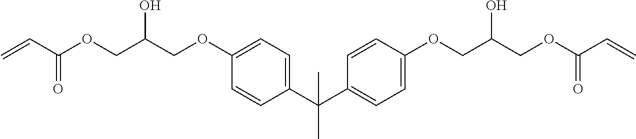

BFA-2: NK ESTERA-BPE-4, manufactured by Shin Nakamura Chemical Industry Co.

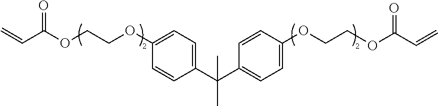

FA: NK ESTER A-BPEF, manufactured by Shin Nakamura Chemical Industry Co.

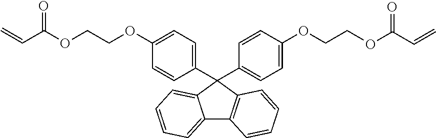

(Acidic Compound which is Polymerizable Compound, Oligomer, or Polymer)

Structures of acidic compounds which are polymerizable compounds, oligomers, or polymers are shown below. Any of PA, CA-1, CA-2, and PP is an acidic (meth)acrylate, oligomer, or polymer thereof.

PA: KARAMER PM-21, manufactured by Nippon Kayaku Co.

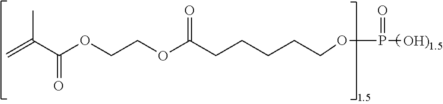

CA-1: NK ESTER ACB-21, manufactured by Shin Nakamura Chemical Industry Co.

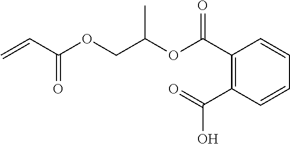

CA-2: NK ESTER CBX-O, manufactured by Shin Nakamura Chemical Industry Co.

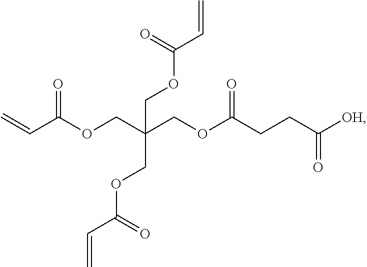

PP: POLYPHOSMER PE-201, manufactured by DAP Co.

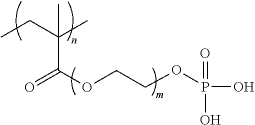

PS: ATBS, manufactured by Toa Gosei Co.

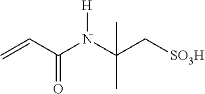

### (Polymerizable Compound)

Structures of polymerizable compounds are shown below.

Any of TMPTA, BEPGA, and PETA is a polyfunctional polymerizable compound.

TMPTA: Trifunctional, manufactured by DAICEL-CYTEC Company LTD.

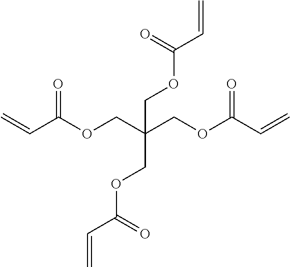

BEPGA: Bifunctional, manufactured Kyoeisha Chemical Co., Ltd.

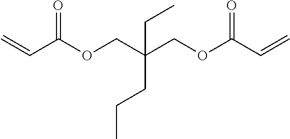

PETA: Tetrafunctional, manufactured by DAICEL-CYTEC Company LTD.

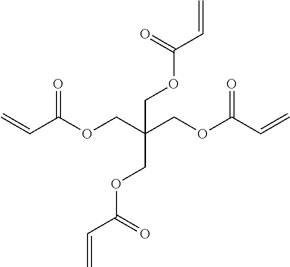

### (Silane Coupling Agent)

Structures of silane coupling agents are shown below. Each of them has a dimethoxydimethylsilyl group or a trimethoxysilyl group.

SC-1: KBM-5103, manufactured by Shin-Etsu Chemical Industry Co.

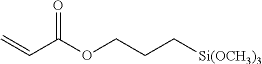

SC-2: KBM-503, manufactured by Shin-Etsu Chemical Industry Co.

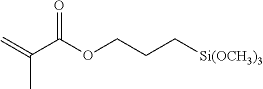

SC-3: KBM-502, manufactured by Shin-Etsu Chemical Industry Co.

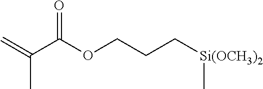

### (1-6) Evaluation of Gas Barrier Film

### <Adhesion Test>

With an aim of evaluating the adhesion of the first organic film and the second organic film with the inorganic layer (X), a cross-cut test was performed according to JIS K 5400. To the surface of a film laminated with the inorganic layer (X), cuttings were formed to the film surface at 90° at 1 mm spacing to prepare 100 check board patterns each at 1 mm spacing. A Mylar tape [polyester film (No. 31B), manufactured by Nit to Denko Co.] of 2 cm width was bonded thereover and the bonded tape was peeled by using a tape peeling tester. The number of board patterns, among 100 check board patterns, which were remained not peeled on the film was counted and the adhesion was evaluated.

### <Measurement of Water Vapor Permeability by Calcium Method>

Water vapor permeability (g/m²/day) was measured by the method described in G. NISATO, P. C. P. BOUTEN, P. J. SLIKKERVEER, et al., SID Conference Record of the International Display Research Conference, pages 1435 to 1438. In this case, the temperature was 40° C. and the relative humidity was 90%.

### <Bending Resistance Test>

The bending resistance was measured by using the method described below.

Bending was applied on each of samples with the film deposition surface being outside by a cylindrical mandrel method (JIS K5600-5-1). After the test, presence or absence of crackings was confirmed by an optical microscope and the maximum diameter (mm) where crackings were not formed was defined as a bendability value.

The layer constitution of the gas barrier layer and the result of evaluation for each of characteristic of the obtained gas barrier film are described in the following Table 4.

TABLE 4

| | | Layer constitution of barrier laminate | | | | | | | | |
|---|---|---|---|---|---|---|---|---|---|---|
| | | Intermediate | | | | | | Characteristic of gag barrier film | | |
| | | organic layer | First | First | Intermediate | Second | Second | Water vapor | Number of | Bending |
| | Base | on the side of | inorganic | organic | organic | organic | inorganic | permeability | not peeled | resistance |
| | film | base film | layer | layer | layer | layer | layer | (g/cm²/day) | checks | (mm) |
| Example 1 | PEN | Y-6 | X | UL-1 | | TL-3 | X | 0.003 | 100 | 7 |
| Example 2 | PEN | Y-6 | X | UL-6 | | TL-2 | X | 0.003 | 60 | 10 |
| Example 3 | PEN | Y-6 | X | UL-1 | | TL-1 | X | 0.001 | 100 | 7 |
| Example 4 | PEN | Y-6 | X | UL-2 | | TL-1 | X | 0.002 | 70 | 9 |
| Example 5 | PEN | Y-6 | X | UL-3 | | TL-1 | X | 0.002 | 70 | 9 |
| Example 6 | PEN | Y-6 | X | UL-4 | | TL-1 | X | 0.001 | 100 | 7 |
| Example 7 | PEN | Y-6 | X | UL-5 | | TL-3 | X | 0.002 | 60 | 10 |
| Example 8 | PEN | Y-6 | X | UL-6 | | TL-1 | X | 0.002 | 60 | 10 |
| Example 9 | PEN | Y-6 | X | UL-7 | | TL-4 | X | 0.001 | 100 | 7 |
| Example 10 | PEN | Y-6 | X | UL-8 | | TL-5 | X | 0.001 | 100 | 7 |
| Example 11 | PEN | Y-6 | X | UL-1 | Y-1 | TL-1 | X | 0.003 | 55 | 10 |
| Example 12 | PEN | Y-6 | X | UL-7 | Y-2 | TL-4 | X | 0.003 | 50 | 10 |
| Example 13 | PEN | Y-6 | X | UL-8 | Y-3 | TL-5 | X | 0.002 | 60 | 10 |
| Example 14 | PEN | Y-6 | X | UL-1 | Y-4 | TL-4 | X | 0.003 | 50 | 10 |
| Example 15 | PEN | Y-6 | X | UL-1 | Y-5 | TL-5 | X | 0.002 | 60 | 10 |
| Example 16 | PEN | Y-6 | X | UL-1 | | TL-6 | X | 0.001 | 100 | 7 |
| Example 17 | PEN | Y-6 | X | UL-9 | | TL-1 | X | 0.001 | 90 | 7 |
| Comp. Example 1 | PEN | Y-6 | X | UL-11 | | TL-1 | X | 0.005 | 20 | 15 |
| Comp. Example 2 | PEN | Y-6 | X | UL-12 | | TL-1 | X | 0.005 | 20 | 15 |
| Comp. Example 3 | PEN | Y-6 | X | UL-11 | | none | X | 0.007 | 15 | 17 |
| Comp. Example 4 | PEN | Y-6 | X | UL-12 | | none | X | 0.007 | 15 | 17 |
| Comp. Example 5 | PEN | Y-6 | X | UL-1 | | none | X | 0.005 | 20 | 15 |
| Comp. Example 6 | PEN | Y-6 | X | none | | TL-1 | X | 0.007 | 10 | 17 |
| Comp. Example 7 | PEN | Y-6 | X | none | | Y-1 | X | 0.007 | 5 | 20 |

As apparent from the result of Table 4, it was found that the adhesion was improved in a structure where two or more organic layers were laminated by introducing an acidic compound which is a polymerizable acidic compound, oligomer, or polymer only to the lower layer. Further, it was found that a low water vapor permeability could be attained by introducing a polyfunctional (meth)acrylate having an aromatic group only to the upper layer. Further, it was found that the adhesion could be improved further by using a (meth)acrylate having an acidic group at the terminal end as the polymerizable acidic compound.

### 2. Manufacture and Evaluation of Organic EL Device

### (2-1) Manufacture of Organic EL Device

After cleaning a conductive glass substrate having an ITO film (surface resistance value 10 Ω/square) with 2-propanol, an UV-ozone treatment was performed for 10 minutes. The following organic compound layers were vapor deposited successively on the substrate (anode) by a vacuum vapor deposition method.

| | |
|---|---|
| (First hole transporting layer) | |
| Copper phthalocyanine | 10 nm thickness |
| (Second hole transporting layer) | |
| N,N′-diphenyl-N,N′-dinaphthyl benzidine | 40 nm thickness |
| (Light-emitting layer also serving | |
| as electron transporting layer) | |
| Tris (8-hydroxyqunolinato) aluminum | 60 nm thickness |

Finally, 1 nm lithium fluoride and 100 nm metallic aluminum were successively vapor deposited to form a cathode, on which a silicon nitride film of 5 μm thickness was deposited by a parallel plate CVD method to prepare an organic EL device.

### (2-2) Disposition of Gas Barrier Layer on Organic EL Device

Using a thermosetting adhesive (Epotex 310, manufactured by Daizo-Nichimori Co.), the gas barrier films of Examples 3 to 16 were appended to organic ELT devices respectively, and the adhesive was hardened by heating at 65° C. or 3 hours. The organic EL devices sealed as described above were prepared each by the number of 20 devices.

### (2-3) Evaluation for the State of Light Emitting Surface of the Organic EL Device

The organic EL devices just after manufacture were caused to emit light by application of a voltage at 7V using a SMU2400 model Source Measure Unit, manufactured by Keithley Co. When the state of the light emitting surface was observed by using a microscope, it has been confirmed that each of the devices gives uniform light emission with no dark spot.

Then, after standing each of the devices stationarily in a dark room at 60° C. and at 90% relative humidity for 500 hours, the state of the light emitting surface was observed. The failure rate of the devices in which dark spots larger than 300 μm diameter were observed was 5% or less in each of the samples of the invention.

### 3. Manufacture of Gas Barrier Film (2)

### Comparative Example 21

A gas barrier film 2a was manufactured in the same manner as the manufacturing method for specimen No. 14 described in the example of JP-A 2010-6063 except for changing the thickness of the organic layer to 500 nm and the thickness of the inorganic layer of silicon oxide to 40 nm. In the obtained gas barrier film, the water vapor permeability was 0.01 g/m²/day, the number of not peeled check patterns was 100, and the bending resistance was 8 mm.

Then, a gas barrier film 2b was manufactured by laminating identical organic layer and inorganic layer each by one layer on the gas barrier film 2a. The layer constitution of the gas barrier film is PEN/organic layer/inorganic layer/organic layer/inorganic layer. The water vapor permeability of the obtained gas barrier film was 0.006 g/m²/day, the number of not peeled check patterns was 20, and the bending resistance was 15 mm.

### Example 21

Further, a gas barrier film 2c in which UL-1 described in Table 1 at 500 nm thickness was added between the gas barrier film 2b and the organic layer just above the inorganic layer was manufactured. The layer constitution of the gas barrier is PET/organic layer/inorganic layer/UL-1/organic layer/inorganic layer. In the obtained gas barrier film, the water vapor permeability was 0.002 g/m²/day, the number of not peeled check patterns was 100, and the bending resistance was 7 mm.

As described above, it was found that the gas barrier film 2c of the invention was excellent in the adhesion, improved further for the bending resistance, and could attain low water vapor permeability compared with the gas barrier film 2b.

While the present invention has been described in detail and with reference to specific embodiments thereof, it will be apparent to one skilled in the art that various changes and modifications can be made therein without departing from the spirit and scope thereof.

The present disclosure relates to the subject matter contained in Japanese Patent Application No. 2010-69319 filed on Mar. 25, 2010, the contents of which are expressly incorporated herein by reference in their entirety. All the publications referred to in the present specification are also expressly incorporated herein by reference in their entirety.

The foregoing description of preferred embodiments of the invention has been presented for purposes of illustration and description, and is not intended to be exhaustive or to limit the invention to the precise form disclosed. The description was selected to best explain the principles of the invention and their practical application to enable others skilled in the art to best utilize the invention in various embodiments and various modifications as are suited to the particular use contemplated. It is intended that the scope of the invention not be limited by the specification, but be defined claims set forth below.

What is claimed is:

1. A method of manufacturing an organic/inorganic laminate comprising:
forming a first organic layer by laminating and hardening a composition for a first organic layer containing (A) an acidic compound which is a polymerizable acidic compound, oligomer or polymer, (B) a polymerizable compound, and (C) a silane coupling agent on a first inorganic layer, and
forming a second organic layer by laminating and hardening a composition for a second organic layer containing (D) a polymerizable compound and (E) a (meth)acrylate having an aromatic group on the first organic layer or on one or more organic layers disposed on the first organic layer.

2. The method of manufacturing an organic/inorganic laminate comprising:
forming a first organic layer by laminating and hardening a composition for a first organic layer containing (A) an acidic compound which is a polymerizable acidic compound, oligomer or polymer, (B) a polymerizable compound, an (C) a silane coupling agent on a first inorganic layer,
forming a second organic layer by laminating and hardening a composition for a second organic layer containing (D) a polymerizable compound and (E) a (meth)acrylate having an aromatic group on the first organic layer or on one or more organic layers disposed on the first organic layer, and
forming a second inorganic layer on the second organic layer.

3. The method of manufacturing an organic/inorganic laminate according to claim 1, wherein the composition for the second organic layer is laminated on the first organic layer.

4. The method of manufacturing an organic/inorganic laminate according to claim 1, wherein a polyfunctional (meth)acrylate is contained as at least one of (B) the polymerizable compound in the composition for the first organic layer, or (D) the polymerizable compound in the composition for the second organic layer.

5. The method of manufacturing an organic/inorganic laminate according to claim 1, wherein a polyfunctional aromatic ring (meth)acrylate is contained as (E) the (meth)acrylate having the aromatic group in the composition for the second organic layer.

6. The method of manufacturing an organic/inorganic laminate according to claim 1, wherein a (meth)acrylate having a bisphenol skeleton is contained as (E) the (meth)acrylate having the aromatic group in the composition for the second organic layer.

7. The method of manufacturing an organic/inorganic laminate according to claim 1, wherein the main ingredient contained in the composition for the first organic layer and the main ingredient contained in the composition for the second organic layer are the same.

8. The method of manufacturing an organic/inorganic laminate according to claim 1, wherein (A) the acidic compound, which is the polymerizable acidic compound, oligomer, or polymer is an acidic (meth)acrylate, oligomer, or polymer thereof.

9. The method of manufacturing an organic/inorganic laminate according to claim 1, wherein (A) the acidic compound which is the polymerizable acid compound, oligomer thereof, or polymer is a phosphoric acid acrylate oligomer or polymer.

10. The method of manufacturing an organic/inorganic laminate according to claim 1, wherein at least one of the first inorganic layer and the second inorganic layer is an inorganic layer containing one of silicon oxide, silicon nitride, silicon oxynitride, and silicon carbide.

11. The method of manufacturing an organic/inorganic laminate according to claim 1, wherein each of the first inorganic layer and the second inorganic layer is an inorganic layer containing one of silicon oxide, silicon nitride, silicon oxynitride, and silicon carbide.

12. The method of manufacturing an organic/inorganic laminate according to claim 1, wherein each of the composition for the first organic layer and the composition for the second organic layer contains a solvent.

13. The method of manufacturing an organic/inorganic laminate according to claim 1, wherein each of the composition for the first organic layer and the composition for the second organic layer contains a photopolymerization initiator.

14. The method of manufacturing an organic/inorganic laminate according to claim 1, wherein the composition for the second organic layer contains (F) a silane coupling agent.

15. The method of manufacturing an organic/inorganic laminate according to claim 14, wherein a compound identical with (F) the silane coupling agent contained in the composition for the second organic layer is contained as (C) the silane coupling agent contained in the composition for the first organic layer.

16. A method of manufacturing an organic/inorganic laminate according to claim 14, wherein (C) the silane coupling agent contained in the composition for the first organic layer and (F) the silane coupling agent contained in the composition for the second organic layer independently have a dimethoxymethylsilyl group or a trimethoxysilyl group respectively.

17. The organic/inorganic laminate manufactured by the method of manufacturing the organic/inorganic laminate according to claim 1.

18. An organic/inorganic laminate in which a first inorganic layer, a first organic layer containing a polymer, and a second organic layer containing a polymer are laminated in this order wherein one or more organic layers may be laminated between the first organic layer and the second organic layer, acidic groups and siloxane bonds are contained in the first organic layer, an M-O—Si bond is formed between an atom M constituting the first inorganic layer and an Si atom constituting the first organic layer, aromatic ring structures and siloxane bonds are contained in the second organic layer, and the acid value of the first organic layer is greater than the acid value of the second organic layer.

19. An organic/inorganic laminate in which a first inorganic layer, a first organic layer containing a polymer, and a second organic layer containing a polymer are laminated in this order wherein one or more organic layers may be laminated between the first organic layer and the second organic layer, acidic groups and siloxane bonds are contained in the first organic layer, an M-O—Si bond is formed between an atom M constituting the first inorganic layer and an Si atom constituting the first organic layer, aromatic ring structures and siloxane bonds are contained in the second organic layer, the acidic value of the first organic layer is greater than the acidic value of the second organic layer, and an M′-O—Si bond is formed between an atom M′ constituting the second inorganic layer and an Si atom constituting the second organic layer.

20. The organic/inorganic laminate according to claim 18, wherein the first organic layer is adjacent with the second organic layer.

21. The organic/inorganic laminate according to claim 18, wherein at least one of the first organic layer and the second organic layer contains a poly(meth)acrylate.

22. The organic/inorganic laminate according to claim 18, wherein the second organic layer contains poly(meth)acrylate having an aromatic group.

23. The organic/inorganic laminate according to claim 18, wherein the second organic layer contains a (meth)acrylate having a poly-bisphenol skeleton.

24. The organic/inorganic laminate according to claim 18, wherein the first organic layer contains a poly(meth)acrylate having an acidic group.

25. The organic/inorganic laminate according to claim 24, wherein the acidic group is a phosphoric acid group.

26. The organic/inorganic laminate according to claim 19, wherein at least one of the first inorganic layer and the second inorganic layer is an inorganic layer containing one of silicon oxide, silicon nitride, silicon oxynitride, and silicon carbide.

27. The organic/inorganic laminate according to claim 19, wherein each of the first inorganic layer and the second inorganic layer is an inorganic layer containing one of silicon oxide, silicon nitride, silicon oxynitride, and silicon carbide.

28. The organic/inorganic laminate according to claim 19, wherein an Si atom constituting the siloxane bond contained in the first organic layer is connected with at least one kind of organic groups, and an Si atom constituting the siloxane bond contained in the second organic layer is connected to the same kind of the organic group as that of the organic group.

29. The organic/inorganic laminate according to claim 18, wherein the total thickness of the organic layers contained between the first inorganic layer and the second inorganic layer is from 0.1 to 50 μm.

30. The organic/inorganic laminate according to claim 18, which is a barrier laminate.

31. A gas barrier film in which the organic/inorganic laminate of claim 18 is formed on a base film.

32. A device using the gas barrier film of claim 31 as a substrate.

33. A device sealed by using the organic/inorganic laminate of claim 18.

34. The device according to claim 32, wherein the device is a solar battery or an organic EL device.
